(19) United States
(12) Patent Application Publication
(10) Pub. No.: US 2023/0313015 A1
(43) Pub. Date: Oct. 5, 2023

(54) DIRECT SINGLE PHASE IMMERSION COOLANT LIQUID

(71) Applicant: Neste Oyj, Espoo (FI)

(72) Inventors: Jukka HARTIKAINEN, Porvoo (FI); David THOMAS, Porvoo (FI)

(73) Assignee: Neste Oyj, Espoo (FI)

(21) Appl. No.: 18/042,019

(22) PCT Filed: Aug. 19, 2021
(86) PCT No.: PCT/FI2021/050558

§ 371 Date: Feb. 17, 2023

(30) Foreign Application Priority Data
Aug. 21, 2020 (FI) 20205816

(51) Int. Cl. C09K 5/10; C10G 3/00; H05K 7/20

(52) U.S. Cl. CPC C09K 5/10; C10G 3/50; H05K 7/20236; H05K 7/20781; C10G 2300/1014; C10G 2300/301; C10G 2300/308; C10G 2300/304; C10G 2300/202; C10G 2300/205; C10G 2300/302

(57) ABSTRACT

A renewable paraffinic composition is disclosed that contains at least 80 wt-% paraffins in a C16-C19 range for direct single phase immersion cooling. A direct single phase immersion cooling system and a method for direct single phase immersion cooling are also disclosed.

### TECHNICAL FIELD

The present disclosure generally relates to direct single phase immersion cooling. The disclosure relates particularly, though not exclusively, to use of a renewable paraffinic composition for direct single phase immersion cooling.

### BACKGROUND

This section illustrates useful background information without admission of any technique described herein representative of the state of the art.

In recent years more data has been created than ever before in human history and much of it is stored in data centers housing computer systems and associated components. Conventionally, air cooling or air circulation has been used for cooling the computer systems. It has been estimated that roughly 40% of the energy consumption of a data center is by air cooling electronics, and that the carbon footprint of data centers is larger than that of the airline industry.

Recently, liquid cooling has begun to be used as an alternative for air cooling in data centers. It has been estimated that significant savings in both cost and energy consumption could be achieved by replacing air cooling with liquid cooling. Furthermore, it has been estimated that liquid cooling could support larger power loads per rack compared to air cooling.

The main liquid cooling options are two phase and single phase liquid cooling.

In two-phase liquid cooling, the coolant liquid has a boiling point below or at the temperature of operation causing the liquid to evaporate thus keeping the temperature of the liquid at its boiling temperature. The formed vapor phase is cooled down to liquid and returned to the coolant liquid.

In single phase liquid cooling the coolant liquid does not undergo phase change. Single phase cooling can either be direct or indirect single phase cooling. In indirect single phase cooling, the coolant liquid is not in contact with any computer system or associated components, whereas in direct single phase liquid cooling, sometimes referred to as direct single phase immersion cooling, computer hardware is directly immersed into the coolant liquid which thus comes into contact with the hardware.

Direct single phase liquid cooling is more simple and less costly compared to two phase liquid cooling or to indirect liquid cooling. However, the effect of a coolant liquid on computer hardware can be significant. Many uncertainties and concerns exist regarding the effects of coolant liquids on computer hardware hindering wide implementation of direct single phase liquid cooling systems in data centers.

Some coolant liquids for direct single phase cooling have, however, been suggested. These liquids are mainly perfluorocarbon liquids, such as the liquids marketed under the 3M™ Fluorinert™ and 3M™ Novec™ brands, e.g. 3M™ Fluorinert™ FC-40, FC-72, and FC-770. These liquids have some attractive properties, such as inertness and stability. However, some drawbacks have been identified. For example, fluorocarbon compounds are known to be extremely potent greenhouse gases and to be persistent in nature. Therefore, for example, disposal of these liquids, and of components that have been immersed in these liquids, may cause challenges. Further, upon combustion, said fluorocompounds form hydrogen fluoride (HF), which poses a real danger for example in the case of fire at a data center facility.

### SUMMARY

It is an aim to solve or alleviate at least some of the problems related to prior direct single phase liquid cooling. In particular, an aim is to provide more environmentally sustainable and climate friendly direct single phase immersion cooling.

The appended claims define the scope of protection.

According to a first aspect there is provided use of a renewable paraffinic composition comprising at least 80 wt-% paraffins in the C16-C19 range based on the total weight of the renewable paraffinic composition for direct single phase immersion cooling.

According to a second aspect there is provided a direct single phase immersion cooling system comprising:
a bath comprising:
   renewable paraffinic composition comprising at least 80 wt-% paraffins in the C16-C19 range based on the total weight of the renewable paraffinic composition, and
an object to be cooled immersed in the renewable paraffinic composition.

According to a third aspect there is provided a method for single phase immersion cooling comprising:
providing a bath comprising a renewable paraffinic composition comprising at least 80 wt-% paraffins in the C16-C19 range based on the total weight of the renewable paraffinic composition; and
immersing an object to be cooled in the renewable paraffinic composition.

### BRIEF DESCRIPTION OF THE FIGURES

Some example embodiments will be described with reference to the accompanying figures, in which:

FIG. 1 shows a schematic drawing of a direct single phase immersion cooling system according to an example embodiment;

FIGS. 2a) and 2b) show a schematic drawing of the test setup of Example 2; and a picture of the test setup of Example 2 in use, respectively;

FIGS. 3a) and 3b) show pictures of a motherboard piece before and after immersion according to test T1, respectively;

FIGS. 3c) and 3d) show pictures of a motherboard piece before and after immersion according to test T2, respectively;

FIGS. 3e) and 3f) show pictures of a motherboard piece before and after immersion according to test T3, respectively;

FIGS. 3g) and 3h) show pictures of a motherboard piece before and after immersion according to test T4, respectively;

FIGS. 3i) and 3j) show pictures of a motherboard piece before and after immersion according to test T5, respectively;

FIGS. 3k) and 3l) show pictures of a motherboard piece before and after immersion according to test T6, respectively;

FIGS. 4a) and 4b) show pictures of RAM boards before and after immersion in P2 and FC-40, respectively;

FIGS. 4c) and 4d) show pictures of RAM boards before and after immersion in P2 and FC-40, respectively;

FIG. 5 shows distillation curves of P2 and of FC-40;

FIG. 6a) shows dynamic viscosity of P2, FC-40, and S5X, respectively, as a function of temperature within the temperature range from 15° C. to 50° C., the lines indicating simulated values and the dots indicating measured values;

FIG. 6b) shows density of P2, FC-40, and S5X, respectively, as a function of temperature within the temperature range from 15° C. to 50° C., the lines indicating simulated values and the dots indicating measured values;

FIG. 6c) shows specific heat capacity (massic heat capacity) of P2, FC-40, and S5X, respectively, as a function of temperature within the temperature range from 15° C. to 50° C., the lines indicating simulated values and the dots indicating measured values;

FIG. 6d) shows thermal conductivity of P2, FC-40, and S5X, respectively, as a function of temperature within the temperature range from 15° C. to 50° C., the lines indicating simulated values and the dots indicating measured values;

FIG. 7 shows a schematic drawing of a flowsheet used in data center cooling simulations of Example 4.

### DETAILED DESCRIPTION

It is generally known that alkane and paraffin are synonyms and can be used interchangeably. In the context of this disclosure, paraffin or paraffins refer to isoparaffins and/or n-paraffins. Isoparaffins (i-paraffins) are branched, open chain paraffins, and normal paraffins (n-paraffins) are unbranched linear paraffins. In other words, the term paraffin or paraffins refers herein to non-cyclic paraffins.

In certain embodiments, the isoparaffins have one or more C1-C9, typically C1-C2, alkyl side chains. Preferably, the side chains are methyl side chains, and the isoparaffins are mono-, di-, tri- and/or tetramethyl substituted.

Boiling range covers in the context of this disclosure a temperature interval from the initial boiling point, IBP, defined as the temperature at which the first drop of distillation product is obtained, to a final boiling point, FBP, when the highest-boiling compounds evaporate.

EN ISO 3405:2011 and ASTM D86:2015 standards “Standard Test Method for Distillation of Petroleum Products and Liquid Fuels at Atmospheric Pressure”, as well as ASTM D7345:2017 standard “Standard Test Method for Distillation of Petroleum Products and Liquid Fuels at Atmospheric Pressure (Micro Distillation Method)” describe a distillation method for measuring the boiling point distribution of liquid fuel products having boiling range within a range from 0° C. to 400° C. (ASTM D7345: 20° C. to 400° C.). Using ASTM D86 or ASTM D7345, boiling points are measured at 25 vol-% distilled. The points may also be reported at 88 vol-% distilled. Said methods are suitable for measuring the boiling point distribution of the renewable paraffinic composition of the present disclosure.

All standards referred herein are the latest revisions available, unless otherwise mentioned.

As used herein, hydrotreatment means a catalytic process for treating organic material by all means of molecular hydrogen. Preferably, hydrotreatment removes oxygen from organic compounds containing oxygen as water i.e. by hydrodeoxygenation (HDO). Additionally or alternatively, hydrotreatment may remove sulphur from organic compounds containing sulphur as dihydrogen sulphide (H2S), i.e. by hydrodesulphurisation, (HDS), remove nitrogen from organic compounds containing nitrogen as ammonia (NH3), i.e. by hydrodenitrofication (HDN), and/or remove halogens, for example chlorine, from organic compounds containing chloride as hydrochloric acid (HCl), i.e. by hydrodechlorination (HDCl).

The term hydrodeoxygenation (HDO), of for example triglycerides or other fatty acid derivatives or fatty acids, means in the context of this disclosure removal of oxygen, such as carboxyl oxygen, as water by means of molecular hydrogen under the influence of a catalyst.

The term deoxygenation means in the context of this disclosure removal of oxygen from organic molecules, such as fatty acid derivatives, alcohols, ketones, aldehydes and/or ethers, by any means previously described, or decarboxylation or de-carbonylation.

The present disclosure provides use of a renewable paraffinic composition comprising at least 80 wt-% paraffins in the C16-C19 carbon number range based on the total weight of the renewable paraffinic composition for direct single phase immersion cooling (in direct single phase immersion cooling) or as a coolant liquid for direct single phase immersion cooling (in direct single phase immersion cooling). Said renewable paraffinic composition remains in liquid form over a wide temperature range, wherefore it may also be referred to as renewable paraffinic liquid.

It has surprisingly been found that a renewable paraffinic composition comprising at least 80 wt-% paraffins in the C16-C19 carbon number range is particularly suitable for direct single phase immersion cooling. At least 80 wt-% paraffins in the C16-C19 range provides the renewable paraffinic composition simultaneously with a high flash point and low kinematic viscosity, which may not be achieved by compositions comprising largely lighter and/or heavier paraffins. A high flash point improves safety and a low kinematic viscosity facilitates circulating the coolant liquid through all components of an object to be cooled, reaching even very tiny cavities thereof (reaching essentially all outer surfaces of the object to be cooled), and thus also improving the heat exchange between the object to be cooled and the coolant liquid. When the coolant liquid is able to reach essentially all outer surfaces, even the very tiny cavities, of an object to be cooled the formation of local hotspots is reduced and rapid cooling of local hot spots, should any emerge, is enabled. A further advantage of a high amount of paraffins in the C16-C19 range is that such coolant liquids are stable, non-toxic, non-corrosive, and form CO and CO₂ upon combustion, for example in case of fire in the operating facility. CO and CO₂ are far less hazardous compared to HF formed upon combustion of prior art fluorocarbon liquids. Furthermore, C16-C19 paraffins are classified as readily biodegradable according to OECD Test Guideline 301 F, which is an advantage, for example, over prior art fluorocarbon liquids which are persistent in nature. Furthermore, the renewable paraffinic composition of the present invention has a relatively low density which is an advantage as it facilitates circulation or pumping of the renewable paraffinic composition in a cooling system, which e.g. reduces electricity consumption. Further, a relatively low density reduces the weight of a bath comprising renewable paraffinic composition which facilitates for example stacking of immersion cooling baths on top of each other. A relatively low density is also advantageous in embodiments where the coolant liquid is not circulated through a heat exchanging unit, but the immersion bath is configured to contain a large enough amount of the renewable paraffinic composition to enable cooling without circulating it through a heat exchanging unit. It has also surprisingly been found that a renewable paraffinic composition comprising at least 80 wt-% paraffins in the C16-C19 carbon number range has beneficial heat transfer and heat absorption properties and is hence particularly suitable for direct single phase immersion cooling. Beneficial heat transfer refers herein to fast heat transfer, and beneficial heat transfer properties are indicated e.g. by a high thermal conductivity and/or a high thermal diffusivity. Coolant liquids with beneficial heat absorption properties may absorb more heat while raising the temperature of the coolant liquid less, and beneficial heat absorption properties are indicated e.g. by a high volumetric heat capacity and/or massic heat capacity.

In certain embodiments, the renewable paraffinic composition comprises 90 wt-% or more, preferably 95 wt-% or more, more preferably 98 wt-% or more paraffins in the C16-C19 range based on the total weight of the renewable paraffinic composition. The abovementioned advantages associated with a high amount of paraffins in the C16-C19 range are particularly pronounced for these compositions. Also, renewable paraffinic compositions comprising 90 wt-% or more C16-C19 paraffins are particularly stable, especially in comparison to e.g. ester based compositions or glyceride based compositions, but also composition comprising a significant amount of olefins. A high content of non-cyclic paraffins also ensures a low oxygen content of the renewable paraffinic composition. Significant oxygen content in direct single phase immersion coolant liquids may lead to a rise of the acidity number and to sludge formation which may be detrimental for the immersed object and/or the direct single phase cooling system, and which sludge formation may hinder efficient heat exchange especially if sludge is accumulated or formed on the immersed object to be cooled.

In certain embodiments, the use of the renewable paraffinic composition comprises circulating renewable paraffinic composition through a heat exchanging unit. The heat exchanging unit is not particularly limited and may be any heat exchanging unit suitable for cooling the renewable paraffinic composition. Preferably, the heat exchanging unit is configured to cool the renewable paraffinic composition.

In certain embodiments, the use of the renewable paraffinic composition is for direct single phase immersion cooling of electronic hardware (in direct single phase immersion cooling of electronic hardware), preferably computer hardware, more preferably a server, or for direct single phase immersion cooling of a fuel cell (in direct single phase immersion cooling of a fuel cell). In direct single phase immersion cooling of electronic hardware, the renewable paraffinic composition is in direct contact with the electronic hardware immersed therein. Similarly, in direct single phase immersion cooling of fuel cells, a fuel cell or a fuel cell stack is immersed directly into the renewable paraffinic composition. Fuel cells are environmentally friendly energy sources and the present invention provides use of an environmentally friendly coolant liquid for direct single phase immersion cooling of fuel cells (in direct single phase immersion cooling of fuel cells).

Surprisingly, the renewable paraffinic composition of the present invention is compatible with electronic hardware, particularly with sensitive computer hardware, such as servers. Computer hardware often comprise a variety of materials and components including, for example, epoxy resin, polyvinylchloride and/or other plastics, fiber glass, various metals such as steel and aluminum, copper wiring, printed circuit board, transistors, capacitors, resistors, microprocessors, motherboard, RAM board and/or dyes for marking. As illustrated by the Examples, it has surprisingly been found that direct immersion of computer hardware into the renewable paraffinic composition of the present invention does not cause dissolution of or otherwise affect or harm the computer hardware. The Examples show that after immersion in the renewable paraffinic composition of the present invention, computer hardware functions normally without impairments. Also, the dielectric properties of the paraffins of the renewable paraffinic composition are excellent and on par with the requirements of direct single phase immersion cooling of electronic hardware.

As used herein, electronic device or hardware and electric device do not refer to the same thing. An important difference between electronic and electric is that electronic indicates decision making (processing) capability, while electric merely refer to converting electrical energy from one form to another or transferring electrical energy. For example, an electric circuit may simply power a device or machine with electricity, while an electronic circuit can interpret a signal or an instruction and perform a task to suit the circumstance. Hence, electric devices may be regarded passive while electronic devices may be regarded active. These differences in function and capabilities naturally reflect on the structure of electronic versus electric devices.

Typically, electric devices are simple and robust in construction, have no or very few moving parts, and are often larger in physical size compared to electronic devices. Electronic hardware or devices on the other hand are typically highly complex systems comprising a multitude of tiny components of various materials. Electric devices typically operate on notably larger voltages (often AC) compared to electronic devices that tend to operate on rather small voltages (often DC).

The small scale typical for the components of electronic hardware presents challenges to cooling. For example, a microprocessor may contain circuit lines that are just a few micrometers think, and electronic hardware may comprise wires being even of nanometer size. It is important to ensure that all tiny parts of the hardware are properly cooled without damaging any of them. Especially so as poor cooling may even break delicate electronic components, especially as components get smaller and smaller. There is a continuing trend that the number of transistors in a dense integrated circuit doubles about every two years (Moore's law), at the same time as electronic devices are getting smaller and smaller. Therefore, cooling of electronic devices is getting more challenging, and improved solutions are needed.

Due to the differences between electric devices and electronic devices, other considerations must be made when contemplating bringing a liquid into direct contact with a simple electric device than when contemplating bringing a liquid into direct contact with electronic hardware. For example, thermal properties, such as the ability to absorb heat (massic heat capacity, volumetric heat capacity) and heat transferability (thermal conductivity, thermal diffusivity), density, viscosity, and (electrical) conductivity may be considered important properties of a coolant liquid used in direct single phase immersion cooling of electronic hardware.

The temperature of operation of direct single phase immersion cooling of electronic hardware, such as computer hardware, e.g. servers, is typically between room temperature (about 20° C.) and about 65° C. However, under heavy load the temperature of a computer server may be around 90° C. In ASICS based crypto mining devices the temperature may be extended up to about 75° C.

In certain embodiments, the temperature of operation of the direct single phase immersion cooling is within a temperature range from 15° C. to 90° C., preferably from 15° C. to 75° C., more preferably from 20° C. to 65° C. These temperatures are particularly advantageous for direct single phase immersion cooling of computer hardware, such as servers, or other electronic hardware.

The renewable paraffinic composition comprising mainly paraffins in the C16-C19 range has a beneficial evaporation profile, i.e. it does essentially not evaporate at the above-mentioned temperatures of operation. This increases safety of direct single phase immersion cooling and allows use of immersion cooling systems wherein the coolant liquid is in direct contact with surrounding air. However, the renewable paraffinic composition may also be used in sealed cooling systems.

In certain embodiments, the renewable paraffinic composition comprises less than 2 wt-% C15 and lighter paraffins based on the total weight of the renewable paraffinic composition. A low amount of C15 and lighter paraffins is preferred as it provides the renewable paraffinic composition with a high flash point. It also provides the renewable paraffinic composition with particularly good heat transfer and heat absorption properties.

In certain embodiments, the renewable paraffinic composition has a flash point of at least 125° C., preferably at least 135° C., more preferably at least 140° C., even more preferably at least 145° C. as measured according to ENISO2719:2016. As mentioned, the temperature of operation of direct single phase immersion cooling of computer hardware, such as servers, is generally between room temperature and about 65° C., which may in ASICS based crypto mining devices be extended up to about 75° C. Under heavy load the temperature of the server may be around 90° C. A high flash point, e.g. a flash point of at least 125° C., ensures safe use of the renewable paraffinic composition for direct single phase immersion cooling of for example computer hardware.

In certain embodiments, the renewable paraffinic composition has a volumetric specific heat (volumetric heat capacity) within a range from 1.60 MJ/(m³K) to 1.90 MJ/(m³K) as measured according to ASTM D7896-19 at 20° C. In certain embodiments, the renewable paraffinic composition has a thermal conductivity in a range from 0.11 W/(m·K) to 0.15 W/(m·K) as measured according to ASTM D7896-19 at 20° C. In certain embodiments, the renewable paraffinic composition has a thermal diffusivity in a range from 0.06 mm²/s to 0.09 mm²/s as measured according to ASTM D7896-19 at 20° C. Preferably, the renewable paraffinic composition has a volumetric specific heat within a range from 1.60 MJ/(m³K) to 1.90 MJ/(m³K) as measured according to ASTM D7896-19 at 20° C., a thermal conductivity in a range from 0.11 W/(m·K) to 0.15 W/(m·K) as measured according to ASTM D7896-19 at 20° C., and a thermal diffusivity in a range from 0.06 mm²/s to 0.09 mm²/s as measured according to ASTM D7896-19 at 20° C. These properties reflect performance in direct single phase immersion cooling of electronic hardware. A high thermal conductivity and a high thermal diffusivity allows for fast heat transfer from the immersed object to the coolant liquid. A high volumetric specific heat allows the coolant liquid to absorb more heat while increasing the temperature of the coolant liquid less compared to a coolant liquid with a lower volumetric specific heat. In certain embodiments, the renewable paraffinic composition comprises less than 2 wt-% C15 and lighter paraffins based on the total weight of the renewable paraffinic composition and has a flash point of at least 125° C., preferably at least 135° C., more preferably at least 140° C., even more preferably at least 145° C. as measured according to ENISO2719:2016, and/or a volumetric specific heat within a range from 1.60 MJ/(m³K) to 1.90 MJ/(m³K) as measured according to ASTM D7896-19 at 20° C., a thermal conductivity in a range from 0.11 W/(m·K) to 0.15 W/(m·K) as measured according to ASTM D7896-19 at 20° C., and a thermal diffusivity in a range from 0.06 mm²/s to 0.09 mm²/s as measured according to ASTM D7896-19 at 20° C.

In certain embodiments, the renewable paraffinic composition comprises 95 wt-% or more, preferably 98 wt-% or more paraffins in the C16-C19 range based on the total weight of the renewable paraffinic composition and has a flash point of at least 125° C., preferably at least 135° C., more preferably at least 140° C., even more preferably at least 145° C. as measured according to ENISO2719:2016, and/or a volumetric specific heat within a range from 1.60 MJ/(m³K) to 1.90 MJ/(m³K) as measured according to ASTM D7896-19 at 20° C., a thermal conductivity in a range from 0.11 W/(m·K) to 0.15 W/(m·K) as measured according to ASTM D7896-19 at 20° C., and a thermal diffusivity in a range from 0.06 mm²/s to 0.09 mm²/s as measured according to ASTM D7896-19 at 20° C.

In certain embodiments, the renewable paraffinic composition comprises less than 5 wt-%, preferably less than 2 wt-%, C20 and heavier paraffins based on the total weight of the renewable paraffinic composition. Without being bound to any theory, it is believed that impurities tend to accumulate in the heavier hydrocarbon fraction (C20 and heavier), wherefore renewable paraffinic compositions comprising a very low amount of C20 and heavier paraffins, or wherein the amount of C20 and heavier paraffins is minimized (optionally even down to essentially 0 wt-%), may comprise less impurities, e.g. metal impurities, which contribute to a particularly low (electrical) conductivity, such as (electrical) conductivity of less than 1 pS/m at 22° C. A low amount of C20 and heavier paraffins also decreases the density of the renewable paraffinic composition and reduces its kinematic viscosity, compared to compositions with a higher amount of C20 and heavier paraffins.

Preferably, the renewable paraffin composition comprises metals at most 5 ppm by weight of the total weight of the renewable paraffinic composition.

Preferably, the water content of the renewable paraffinic composition is less than 50 ppm by weight based on the total weight of the renewable paraffinic composition. The renewable paraffinic composition of the present disclosure has high water repellency. A low water content and a high water repellency are beneficial when the renewable paraffinic composition is used as a coolant liquid in direct single phase immersion cooling of electronic hardware as electronic hardware is sensitive to moisture.

In certain embodiments, the renewable paraffinic composition has a density within the range from 700 to 850 kg/m³, preferably from 760 to 800 kg/m³, more preferably from 770 to 790 kg/m³ at 20° C. as measured according to EN ISO12185. These densities are significantly lower than densities of prior art fluorocarbon liquids. In other words, a certain volume of renewable paraffinic compositions according to these embodiments has a significantly lower weight or mass than the same volume of a prior art fluorocarbon coolant liquid. An advantage of this is that coolant liquid baths of renewable paraffinic compositions according to these embodiments may easily be stacked on top of each other (in the vertical direction), for example 2 or 3 baths may be stacked on top of each other, without requiring expensive, extra strong materials in the baths and/or the stacking structure and/or the floor or building foundation on which the stacks are situated. Stacking baths on top of each other saves floor space and allows to cool more objects within a certain (floor) area. Further advantages in single phase immersion cooling of renewable paraffinic compositions having relatively low densities include easier circulation of the coolant liquid, as described in the foregoing.

In certain embodiments, the renewable paraffinic composition comprises less than 5 wt-%, more preferably less than 2 wt-%, C20 and heavier paraffins based on the total weight of the renewable paraffinic composition and has a density of 850 kg/m³ or less, preferably 800 kg/m³ or less, more preferably of 790 kg/m³ or less at 20° C. as measured according to EN ISO12185.

In certain embodiments, the renewable paraffinic composition comprises 90 wt-% or more, preferably 95 wt-% or more, more preferably 98 wt-% or more paraffins in the C16-C19 range based on the total weight of the renewable paraffinic composition and has a density within the range from 700 to 850 kg/m³, preferably from 760 to 800 kg/m³, more preferably from 770 to 790 kg/m³ at 20° C. as measured according to EN ISO12185.

In certain embodiments, the renewable paraffinic composition has a boiling range within a range from about 270° C. to about 325° C., preferably from about 275° C. to about 320° C., more preferably from about 280° C. to about 300° C. as measured according to EN ISO03405:2011. For example, the initial boiling point of the renewable paraffinic composition, IBP, may be about 275° C., preferably about 280° C., and the final boiling point, FBP, may be about 320° C., preferably about 300° C. as measured according to EN ISO3405:2011. In certain embodiments, the renewable paraffinic composition has a NOACK150 value of 9 wt-% or less, preferably 8.5 wt-% or less as measured according to ASTMD5800-15a B.

Renewable paraffinic compositions having a high IBP temperature value (such as 275° C. or above) and/or a low NOACK150 value (such as 9 wt-% or less) comprise no or very little volatile compounds and at most a very low content of VOCs. This is an advantage in comparison to prior art perfluorocarbon liquids that are rather volatile and may evaporate almost completely during the NOACK test. In other words, an advantage of a high IBP temperature and/or a low NOACK150 value is that there is no or very little evaporation of the renewable paraffinic composition for example at the temperatures of operation mentioned in the foregoing. This increases safety of direct single phase immersion cooling, e.g. in connection with maintenance, and allows use of direct single phase immersion cooling systems wherein the coolant liquid is in direct contact with surrounding air.

In certain embodiments, the renewable paraffinic composition comprises 95 wt-% or more, preferably 98 wt-% or more paraffins in the C16-C19 range based on the total weight of the renewable paraffinic composition, wherein the initial boiling point of the renewable paraffinic composition, IBP, is about 275° C., preferably about 280° C., and the final boiling point, FBP, is about 320° C., preferably about 300° C. as measured according to EN ISO3405:2011. In certain embodiments, the renewable paraffinic composition comprises 95 wt-% or more, preferably 98 wt-% or more paraffins in the C16-C19 range based on the total weight of the renewable paraffinic composition and the renewable paraffinic composition has a NOACK150 value of 9 wt-% or less, preferably 8.5 wt-% or less as measured according to ASTMD5800-15a B.

In certain embodiments, the renewable paraffinic composition comprises less than wt-% olefins, preferably less than 5 wt-% olefins, more preferably less than 2 wt-% olefins based on the total weight of the renewable paraffinic composition, even more preferably the renewable paraffinic composition is essentially free from olefins. A low olefin content improves the stability of the renewable paraffinic composition. A low olefin content is also advantageous to ensure dielectric behaviour of the renewable paraffinic composition.

In certain embodiments, the renewable paraffinic composition comprises 5 wt-% or less, preferably 2 wt-% or less naphthenes based on the total weight of the renewable paraffinic composition, more preferably the renewable paraffinic composition is essentially free from naphthenes. Naphthenes, particularly several wt-% of naphthenes, in a coolant liquid may cause formation of sludge or precipitates (e.g. microcrystalline wax), which may be detrimental particularly to the performance of the immersed object, but also to the direct single phase immersion cooling system or parts thereof, for example pumps. Sludge or precipitates may also hinder efficient heat exchange especially if deposits are formed on the object to be cooled.

In certain embodiments, the renewable paraffinic composition comprises at least 99 wt-% hydrocarbons of the total weight of the renewable paraffinic composition. In certain embodiments, the renewable paraffinic composition comprises more than 90 wt-%, preferably at least 95 wt-%, more preferably at least 98 wt-% paraffins based on the total weight of the renewable paraffinic composition. A high content of paraffins is preferred because it improves the stability of the renewable paraffinic composition, particularly in comparison to e.g. ester based compositions or glyceride based compositions, but also composition comprising a significant amount of olefins. A high content of paraffins also ensures a low oxygen content of the renewable paraffinic composition. Significant oxygen content in direct immersion coolant liquids may lead to a rise of the acidity number and to sludge formation, as discussed above. Furthermore, renewable paraffinic compositions with a high content of paraffins, such as more than 90 wt-%, may be classified as readily biodegradable according to OECD Test Guideline 301 F.

In certain embodiments, the renewable paraffinic composition comprises more than 90 wt-%, preferably at least 95 wt-%, more preferably at least 98 wt-% paraffins, and at most 10 wt-% C16 paraffins, such as between 2 wt-% and 10 wt-% C16 paraffins, preferably at most 6 wt-% C16 paraffins, such as between 2 wt-% and 6 wt-% C16 paraffins, based on the total weight of the renewable paraffinic composition. A relatively low amount of C16 paraffins in the renewable paraffinic composition, when the C16-C18 paraffin content in the composition is high, further improves, i.e. increases, the flash point of the renewable paraffinic composition. It also improves, i.e. increases, thermal conductivity, thermal diffusivity, and volumetric specific heat of the renewable paraffinic composition.

In certain embodiments, the renewable paraffinic composition comprises more than 90 wt-%, preferably at least 95 wt-%, more preferably at least 98 wt-% paraffins, and at most 2 wt-% C19 paraffins, such as between 1 wt-% and 2 wt-% C19 paraffins, based on the total weight of the renewable paraffinic composition. A relatively low amount of C19 paraffins in the renewable paraffinic composition, when the C16-C19 paraffin content in the composition is high, further decreases the density and the kinematic viscosity of the composition.

In certain embodiments, the renewable paraffinic composition comprises more than 90 wt-%, preferably at least 95 wt-%, more preferably at least 98 wt-% paraffins, and more than 37 wt-% and optionally less than 42 wt-% C17 paraffins, based on the total weight of the renewable paraffinic composition. Such renewable paraffinic compositions perform well as coolant liquids for direct single phase immersion cooling providing an advantageous combination of a high flash point, a low density and a low kinematic viscosity. Such renewable paraffinic compositions also provide good heat transfer and heat absorption properties.

In certain embodiments, the renewable paraffinic composition comprises more than 90 wt-%, preferably at least 95 wt-%, more preferably at least 98 wt-% paraffins, and more than 45 wt-%, preferably more than 48 wt-%, more preferably more than 50 wt-%, and optionally less than 57 wt-% C18 paraffins, based on the total weight of the renewable paraffinic composition. Such renewable paraffinic compositions perform well as coolant liquids for direct single phase immersion cooling providing an advantageous combination of a high flash point, a low density and a low kinematic viscosity. Such renewable paraffinic compositions also provide good heat transfer and heat absorption properties.

In certain embodiments, the renewable paraffinic composition comprises more than 90 wt-% and optionally less than 95 wt-% C17-C18 paraffins. This provides the renewable paraffinic composition with a beneficial combination of a high flash point, even at least 140° C., low density, and low kinematic viscosity providing improved fluidity. Such renewable paraffinic compositions also provide good heat transfer and heat absorption properties.

In certain embodiments, the renewable paraffinic composition comprises more than 90 wt-%,and optionally less than 95 wt-%, paraffins in the C17-C18 range, wherein the ratio of the amount of C18 i-paraffins to the amount of C18 n-paraffins is more than 40, such as between 42 and 47, based on the weight of the C18 i-paraffins and the weight of the C18 n-paraffins in the renewable paraffinic composition. This composition has good performance in direct single phase immersion cooling. The high share of C17-C18 paraffins provides the renewable paraffinic composition with a beneficial combination of a high flash point even of at least 140° C., such as 145° C., low density and decreased kinematic viscosity providing improved fluidity, while the high weight ratio of C18 i-paraffins to C18 n-paraffins provides a yet lower kinematic viscosity and thus better fluidity, this combination ensuring particularly efficient heat transfer and subsequent improved safety of use. Increasing the ratio of C18 i-paraffins to C18 n-paraffins provides a more fluid renewable paraffin composition, while having high volumetric heat capacity, thermal conductivity and thermal diffusivity contributed by the C17-C18 paraffins.

In certain preferred embodiments, the renewable paraffinic composition comprises more than 90 wt-% paraffins in the C17-C18 range, based on the total weight of the composition, wherein the ratio of the amount of C18 i-paraffins to the amount of C18 n-paraffins is more than 40, based on the weight of the C18 i-paraffins and the weight of the C18 n-paraffins in the renewable paraffinic composition, and more than 45 wt-%, preferably more than 48 wt-%, more preferably more than 50 wt-% C18 paraffins, based on the total weight of the renewable paraffinic composition. Such renewable paraffinic compositions perform well as coolant liquids for direct single phase immersion cooling and have good heat transfer and heat absorption properties.

In certain embodiments, the ratio of the amount of C17 i-paraffins to the amount of C17 n-paraffins is more than 20, and preferably less than 30, based on the weight of the C17 i-paraffins and the weight of the C17 n-paraffins in the renewable paraffinic composition. Such renewable paraffinic compositions have particularly good fluidity and a low kinematic viscosity, while having good heat transfer and heat absorption properties, and perform well as coolant liquids for direct single phase immersion cooling.

In certain embodiments, the renewable paraffinic composition comprises 3-4 wt-% C16 isoparaffins, 35-40 wt-% C17 isoparaffins, 50-55 wt-% C18 i-paraffins, 1-3 wt-% C19 isoparaffins, 0.1-1 wt-% C16 n-paraffins, 0.5-2 wt-% C17 n-paraffins, 0.5-2 wt-% C18 n-paraffins and 0.01-1 wt-% C19 n-paraffins, based on the total weight of the renewable paraffinic composition. Such renewable paraffinic compositions perform well as coolant liquids for direct single phase immersion cooling and have good heat transfer and heat absorption properties.

In certain embodiments, the renewable paraffinic composition comprises less than 1 wt-% aromatics, preferably less than 0.5 wt-% aromatics, based on the total weight of the renewable paraffinic composition. A low aromatics content improves safety by reducing health risks associated with aromatic compounds, and also contributes to lower density as aromatics tend to have higher densities than paraffins.

In certain embodiments, the renewable paraffinic composition has a kinematic viscosity below 15 mm²/s, preferably below 10 mm²/s, more preferably below 5 mm²/s at 40° C. as measured according to EN ISO3104. Typically the renewable paraffinic composition has a kinematic viscosity more than 1 mm²/s, such as more than 1.5 mm²/s, or more than 2 mm²/s (at 40° C. as measured according to EN ISO3104). A low kinematic viscosity indicates better fluidity of the renewable paraffinic composition. The better fluidity ensures e.g. that essentially all outer surfaces, including very tiny cavities, of an object to be cooled may be reached by the coolant liquid, more efficient heat transfer, and reduces the risk of local hot spots in the renewable paraffinic composition. Also, a low kinematic viscosity facilitates circulating the coolant liquid in a cooling system.

In certain embodiments, the renewable paraffinic composition has a (electrical) conductivity less than 1 pS/m at 22° C. as measured according to ISO6297:1997. A minimal (electrical) conductivity is advantageous particularly when using the renewable paraffinic composition for immersion cooling of electronic hardware, such as computer hardware.

In certain embodiments, the renewable paraffinic composition comprises more than 60 wt-%, preferably more than 70 wt-%, more preferably more than 80 wt-%, even more preferably more than 90 wt-%, and most preferably more than 95 wt-% isoparaffins based on the total weight of the renewable paraffinic composition. A high isoparaffin content, such as 80 wt-% or more, reduces the kinematic viscosity of the renewable paraffinic composition and improves its fluidity. The reduction of the kinematic viscosity is particularly pronounced at low temperatures. The improved fluidity ensures that e.g. essentially all outer surfaces, even the very tiny cavities, of an object to be cooled may be reached, and the heat transfer efficiency may be improved. Also the risk of local hot spots is reduced, thereby improving life-time of the renewable paraffinic composition and safety. More efficient cooling may also allow tighter packing of objects to be cooled within the immersion bath, and/or reduce the cooling rate. A high isoparaffin content also improves the cold performance of the renewable paraffinic composition, including enhanced fluidity at low temperatures. In certain embodiments, the renewable paraffinic composition comprises more than 90 wt-% and less than 98 wt-% isoparaffins based on the total weight of the renewable paraffinic composition. This denotes good performance, especially in terms of reduced kinematic viscosity and enhanced fluidity, over a broad temperature range.

In certain embodiments, the renewable paraffinic composition comprises more than 90 wt-%, preferably at least 95 wt-%, more preferably at least 98 wt-% paraffins, and more than 60 wt-%, preferably more than 70 wt-%, more preferably more than 80 wt-%, even more preferably more than 90 wt-%, and most preferably more than 95 wt-% isoparaffins.

In certain embodiments, the isoparaffins are methyl substituted isoparaffins.

In certain embodiments, the renewable paraffinic composition has a cloud point below −15° C., preferably below −20° C., more preferably below −25° C., and even more preferably below −30° C. as measured according to ASTMD7689:2017. A low cloud point temperature value ensures that no paraffin crystals precipitate in case of efficient and rapid cooling of the renewable paraffinic composition, which allows e.g. using pumps without filters in the direct single phase immersion cooling system.

In certain embodiments, the renewable paraffinic composition has a pour point below −45° C., preferably below −50° C., more preferably below −55° C., even more preferably below −60° C., and most preferably below −65° C. as measured according to ASTMD5950:2014. A low pour point facilitates for example pumping of the renewable paraffinic composition in connection with efficient and rapid cooling.

Good cold operability, i.e. a low cloud point, such as below −15° C., and/or a low pour point value, such as below −45° C., allows using the renewable paraffinic composition together with very efficient heat exchanging units that rapidly cools down coolant liquid. For example, solidification on surfaces of very efficient heat exchangers may be avoided. Very efficient heat exchanging units allow formation of particularly compact systems for cooling. Cold operability may be enhanced with suitable additives. However, the use of additive(s) to improve cold operability is not necessary when the renewable paraffinic composition has a low cloud point value and/or a low pour point value.

Furthermore, good cold operability allows for example cooling the renewable paraffinic composition by passing it through piping situated outdoors as a renewable paraffinic composition with good cold operability will remain its fluidity also at low outdoor temperatures, such as below −15° C. Also formation of precipitates at low outdoor temperatures is prevented by good cold properties.

A benefit of single phase cooling compared to two phase cooling is that whereas in two phase cooling the temperature of the coolant liquid is kept at the boiling temperature of the coolant liquid, single phase cooling allows operating within a broader temperature range and setting the operating temperature at a desired level. A coolant liquid that remains in liquid form over a wide temperature range is beneficial in that it allows to selected the desired operating temperature or temperature range from a wide temperature range.

In certain embodiments, the renewable paraffinic composition comprises more than 80 wt-%, preferably more than 90 wt-%, and more preferably more than 95 wt-% isoparaffins, and has a cloud point below −15° C., preferably below −20° C., more preferably below −25° C., and even more preferably below −30° C. as measured according to ASTMD7689:2017 and/or a pour point below −45° C., preferably below −50° C., more preferably below −60° C., and even more preferably below −65° C. as measured according to ASTMD5950:2014.

Preferably, the renewal paraffinic composition has a surface tension below 40 mN/m, preferably below 35 mN/m, more preferably the surface tension is 30 mN/m or less as measured according to ASTM D971M.

Preferably, the renewable paraffinic composition has a (electrical) resistivity within a range from 1.0·10¹⁴ Ω·cm to 10·10¹⁵ Ω·cm as measured according to ASTM D1169-19a at 55° C. The renewable paraffinic composition has a negative relationship between (electrical) resistivity and temperature, i.e. (electrical) resistivity decreases upon increasing temperature. The (electrical) resistivity of the renewable paraffinic composition is relatively high even at elevated temperatures that may occur during use.

Preferably, the renewable paraffinic composition has a specific heat capacity (massic heat capacity) within a range from 1.5 kJ/(kg·K) to 3.0 kJ/(kg·K) as measured according to ASTM E1269-11(2018) at 40° C.

Preferably, the renewable paraffinic composition has a breakdown voltage of at least 60 kV, preferably at least 65 kV, more preferably at least 70 kV, and it may be less than 80 kV, or 75 kV or less, as measured according to IEC60156:2018 at 20° C.

Surface tension, (electrical) resistivity, massic heat capacity and/or volumetric heat capacity, and breakdown voltage reflect performance of the renewable paraffinic composition as a coolant liquid in direct single phase immersion cooling of electronic hardware.

In certain embodiments, the renewable paraffinic composition may comprise one or more additives, for example selected from antioxidant additives, metal passivators, pour point depressants, additives decreasing gassing tendency, and/or any other commonly used additive. However, none of these mentioned additives is necessary for the renewable paraffinic composition to adequately function as a coolant liquid for direct single phase immersion cooling, but they may optionally be used alone or in combination with other additives to further improve a certain property or properties of the renewable paraffinic composition.

Preferably, the renewable paraffinic composition is classified as readily biodegradable according to OECD Test Guideline 301 F. The paraffins of the renewable paraffinic composition of the present invention are readily biodegradable which facilitates disposal of the renewable paraffinic composition after it has served as a coolant liquid for direct single phase immersion cooling. Also disposal of components that have been immersed in the renewable paraffinic composition is facilitated. This is a clear advantage over prior art perfluorocarbon based coolant liquids which are very persistent in nature, and therefore need special care and arrangements when disposed, including any objects that have been immersed in said prior art perfluorocarbon liquids.

Optionally, after the renewable paraffinic composition has served as a coolant liquid for direct single phase immersion cooling, the used renewable paraffinic composition may be provided as a feedstock for refineries. The used renewable paraffinic composition may be fed straight into a refinery or undergo pretreatment before being fed to a refinery. Thus, the used renewable paraffinic composition may be processed for example into diesel fuel or chemicals, which enable value added use of the renewable paraffinic once it has served as a coolant liquid for single phase immersion cooling.

In certain embodiments, the renewable paraffinic composition is obtainable or obtained by a method comprising hydrotreatment and optional isomerisation of renewable feedstock to obtain a renewable paraffinic feed; and subjecting the obtained renewable paraffinic feed to at least one separation, or fractionation, process to recover a renewable paraffinic composition comprising at least 80 wt-% paraffins in the C16-C19 range based on the total weight of the renewable paraffinic composition. After hydrotreatment and without isomerisation, the renewable paraffinic feed comprises mainly n-paraffins. After hydrotreatment and isomerisation, the renewable paraffinic feed comprises mainly n-paraffins and isoparaffins, the degree of isomerisation depending on the isomerisation treatment.

Any known separation or fractionation method, or a combination of any know separation and/or fractionation method, suitable for recovering from the renewable paraffinic feed a renewable paraffinic composition as described in the foregoing embodiments may be used.

In certain embodiments, the separation or fractionation process comprises distillation, preferably fractional distillation, of the renewable paraffinic feed. Distillation is also beneficial in that it contributes to removing impurities, such as residual moisture, metals, and/or oxidants. Significant amounts of such impurities could harm sensitive computer hardware if brought into direct contact with it. In certain embodiments, the separation or fractionation process comprises two or more separation or fractionation steps.

In certain embodiments, the separation or fractionation process comprises recovering from the separation or fractionation a renewable paraffinic composition having a boiling range within a range from about 270° C. to about 325° C., preferably from about 275° C. to about 320° C., more preferably from about 280° C. to about 300° C. as measured according to EN ISO3405:2011.

Preferably, the separation or fractionation is selected so that a majority of the paraffins in the C16-C19 range, particularly the isoparaffins in the C16-C19 range, end up in the recovered composition. The separation process may be selected to obtain a renewable paraffinic composition with predefined carbon number, n-paraffin, and i-paraffin distributions. By selecting the separation or fractionation in this way, it is possible to control the viscosity and the density of the recovered hydrocarbon composition. Also the amount of impurities may be reduced as they typically concentrate in the heavier hydrocarbon bottom, thereby further reducing electrical conductivity of the renewable paraffinic composition.

Typically, renewable paraffinic feed obtained through hydrotreatment and optional isomerisation of renewable (biosourced) feedstock has a carbon number distribution in the range from C8 to C22 or from C10 to C20, preferably in the range from C15 to C18, and a boiling range within 140° C.-340° C., preferably within 180° C.-320° C. Selection of renewable feedstock regarding favourable characteristics, such as selecting a renewable feedstock having a high amount of compounds having carbon chain length longer than or equal to C16, may be used to increase the yield of the renewable paraffinic composition.

Most renewable raw material comprise materials having a high oxygen content. In certain embodiments, the renewable feedstock comprises fatty acids, or fatty acid derivatives, such as triglycerides, or a combination thereof. Hydrotreating removes oxygen from the renewable feedstock preferably as water i.e. by hydrodeoxygenation (HDO). Optionally, the production of the renewable paraffinic feed may include other deoxygenation treatment(s) in addition to hydrotreatment. Such deoxygenation treatments are not particularly limited and any suitable deoxygenation treatment may be employed. Suitable treatments include catalytic cracking (CC), decarboxylation and/or decarbonylation reactions.

In certain preferred embodiments, the hydrotreatment is hydrodeoxygenation. Accordingly, in certain embodiments obtaining a renewable paraffinic feed comprises hydrodeoxygenation and optional isomerisation of renewable feedstock. Reaction conditions and catalysts suitable for the hydrodeoxygenation of renewable feedstock and for the optional isomerisation of resultant n-paraffins are known. Examples of such processes are presented in WO 2015/101837 A2, paragraphs [0032]-[0037]. Further, e.g. FI100248, Examples 1-3, shows examples of hydrodeoxygenation and isomerisation of renewable feedstock.

The hydrodeoxygenation is preferably performed at a pressure selected from the range from 2 to 15 MPa, preferably from 3 to 10 MPa, and at a temperature selected from the range from 200 to 500° C., preferably from 280 to 400° C. The hydrodeoxygenation may be performed in the presence of known hydrodeoxygenation catalyst containing metal(s) from Group VIII and/or Group VIB of the Periodic System. The catalyst may be supported on any convenient support, such as alumina, silica, zirconia, titania, amorphous carbon, molecular sieves or combinations thereof. Preferably, the hydrodeoxygenation catalyst is supported Pd, Pt, Ni, or NiW catalyst, or supported Mo containing catalyst, such as NiMo or CoMo, catalyst, wherein the support is alumina and/or silica, or a combination of these catalysts. Typically, NiMo/Al₂O₃ and/or CoMo/Al₂O₃ catalysts are used.

The HDO is preferably carried out in the presence of sulphided NiMo or sulphided CoMo catalysts in the presence of hydrogen gas. The HDO may be performed under a hydrogen pressure selected from the range from 1 to 20 MPa, at temperatures selected from the range from 200° C. to 400° C., and liquid hourly space velocities selected from the range from 0.2 h⁻¹ to 10 h⁻¹. Using a sulfided catalyst, the sulfided state of the catalyst may be maintained during the HDO step by the addition of sulphur in the gas phase or by using a feedstock having sulphur containing mineral oil blended with the renewable feedstock. The sulphur content of the total feedstock being subjected to hydrodeoxygenation may be, for example, in the range from 50 wppm (ppm by weight) to 20 000 wppm, preferably in the range from 100 wppm to 1000 wppm.

Effective conditions for hydrodeoxygenation may reduce the oxygen content of the feedstock to less than 1 wt-%, such as less than 0.5 wt-% or less than 0.2 wt-%. Optionally, the conditions may be selected to yield partial hydrodeoxygenation corresponding to a deoxygenation of at least 40 wt-%, at least 50 wt-% or at least 75 wt-%.

Generally, the renewable paraffinic feed may be produced from the renewable feedstock using any known method. Specific examples of a method for producing the renewable paraffinic feed are provided in EP 1741768 A1, paragraphs [0038]-[0070], particularly paragraphs [0056]-[0070], and Examples 1-6. Also other methods may be employed, particularly another BTL (Biomass-To-Liquid) method may be chosen, for example biomass gasification followed by a Fischer-Tropsch method.

Preparing the renewable paraffinic feed may optionally comprise a step of hydrocracking carbon chains after the hydrotreatment. Thus, the chain length of the formed paraffins may be adjusted and the product distribution of the produced renewable paraffinic feed can be indirectly controlled.

The optional isomerisation treatment is not particularly limited and any suitable isomerisation treatment may be used. However, catalytic isomerisation treatments are preferred. The isomerisation treatment is preferably performed at a temperature selected from the range 200-500° C., preferably 280-400° C., such as 300° C.-350° C., and at a pressure selected from the range 1-15 MPa, preferably 3-10 MPa. The isomerisation treatment may be performed in the presence of known isomerisation catalysts, for example, catalysts containing a molecular sieve and/or a metal selected from Group VIII of the Periodic System and a support. Preferably, the isomerisation catalyst is a catalyst containing SAPO-11 or SAPO-41 or ZSM-22 or ZSM-23 or ferrierite and Pt, Pd, or Ni and Al₂O₃ or SiO₂. Typical isomerisation catalysts are, for example, Pt/SAPO-11/Al₂O₃, Pt/ZSM-22/Al₂O₃, Pt/ZSM-23/Al₂O₃ and/or Pt/SAPO-11/SiO₂. The catalysts may be used alone or in combination. Catalyst deactivation may be reduced by the presence of molecular hydrogen in the isomerisation treatment. In certain preferred embodiments, the isomerisation catalyst is a noble metal bifunctional catalyst, such as Pt-SAPO and/or Pt-ZSM-catalyst, which is used in combination with hydrogen.

At least straight chain paraffins from the hydrotreatment may be subjected to the optional isomerisation treatment, or the hydrotreated renewable feedstock may be subjected to the optional isomerization treatment as a whole. The isomerisation treatment is a step which predominantly serves to isomerise the paraffins obtained from the hydrotreatment step. That is, while most thermal or catalytic conversions (such as HDO) result in a minor degree of isomerisation (usually less than 5 wt-%), the isomerisation step which may optionally be included in producing the renewable paraffinic feed is a step which leads to a significant increase in the content of isoparaffins. The isomerisation step may comprise further intermediate steps such as a purification step and/or a fractionation step.

In embodiments where both a hydrodeoxygenation step and an isomerisation step are applied, these may be performed either simultaneously or in sequence. In certain embodiments, producing the renewable paraffinic feed comprises carrying out hydrodeoxygenation and hydroisomerisation in a single step on the same catalyst bed using a single catalyst for this combined step, e.g. NiW, or a Pt catalyst, such as Pt/SAPO in a mixture with a Mo catalyst on a support, e.g. NiMo on alumina.

In certain embodiments, producing the renewable paraffinic feed comprises performing hydrodeoxygenation in the presence of hydrogen gas and a hydrodeoxygenation catalyst, such as CoMo, NiMo, NiW, CoNiMo, on a support, for example, an alumina support, zeolite support, or a mixed support, preferably NiMo, optionally on an alumina support, and conducting the hydrodeoxygenation reaction at a temperature in the range from 250 to 400° C., and at a pressure in the range from 2 to 8 MPa at a WHSV (weight hourly space velocity, i.e. mass flow/catalyst mass) in the range from 0.5 to 3 h⁻¹, and a H₂/renewable feedstock ratio of 350-900 nl/l, and optionally subjecting the hydrotreated renewable feedstock to an isomerisation step in the presence of hydrogen and an isomerisation catalyst, preferably a noble metal bifunctional catalyst such as Pt-SAPO or Pt-ZSM catalyst or NiW, and conducting the isomerisation reaction at a temperature of 250-400° C. and at a pressure of 1-6 MPa, and at a WHSV of 0.5-3 h−1, and at a H2/oil ratio of 100-800 nl/l. Preferably, in embodiments where a hydrodeoxygenation step and an isomerisation step are performed in sequence, the a hydrodeoxygenation step is followed by the isomerization step.

The yield of the renewable paraffinic composition may be increased by the selection of the process conditions of the renewable paraffinic feed production process.

As used herein, renewable raw material refers to materials and products obtainable, derivable, or originating from plants and/or animals, including materials and products obtainable, derivable, or originating from fungi and/or algae. As used herein, renewable raw material may comprise gene manipulated renewable raw material. Renewable raw material may also be referred to as biological raw material or biogenic raw material.

Fossil raw material or mineral raw material refer in the context of this disclosure to naturally occurring non-renewable compositions, such as crude oil, petroleum oil/gas, shale oil/gas, natural gas, or coal deposits, and the like, and combinations thereof, including any hydrocarbon-rich deposits that can be utilized from ground/underground sources. The term fossil or mineral may also refer to recycling material originating from non-renewable sources.

Carbon atoms of renewable or biological origin comprise a higher number of unstable radiocarbon (¹⁴C) atoms compared to carbon atoms of fossil origin. Therefore, it is possible to distinguish between carbon compounds derived from renewable or biological raw material and carbon compounds derived from fossil raw material by analysing the ratio of ¹²C and ¹⁴C isotopes. Thus, a particular ratio of said isotopes can be used as a “tag” to identify renewable carbon compounds and differentiate them from non-renewable carbon compounds. The isotope ratio does not change in the course of chemical reactions. Examples of a suitable method for analysing the content of carbon from biological or renewable sources are DIN 51637 (2014), ASTM D6866 (2020) and EN 16640 (2017). As used herein, the content of carbon from biological or renewable raw material is expressed as the biogenic carbon content meaning the amount of biogenic carbon in the material as a weight percent of the total carbon (TC) in the material (in accordance with ASTM D6866 (2020) or EN 16640 (2017)). Feedstock or raw material of biological origin (biological raw material) means material having typically only biogenic carbon content.

Typically hydrocarbons made from 100% palm oil have a biogenic carbon content of about 100 wt-%. Typically hydrotreated animal fat has a biogenic carbon content of about 100 wt-%. Typically fossil crude oil based mineral oil has a biogenic carbon content of about 0 wt-%.

Renewable feedstock refer in the context of this disclosure to a feedstock derived from a biological raw material component containing oils and/or fats, usually containing lipids (e.g. fatty acids or glycerides), including renewable oil and/or fat, such as plant oil/fats, wood oil/fats, vegetable oil/fats, animal oil/fats, fish oil/fats and algae oil/fats, or oil/fats from other microbial processes, for example, genetically manipulated algae oil/fats, genetically manipulated oil/fats from other microbial processes and also genetically manipulated vegetable oil/fats. Components or derivatives of such materials may also be used, for example, alkyl esters (typically C1-C5 alkyl esters, such as methyl, ethyl, propyl, iso-propyl, butyl, sec-butyl esters) or olefins. The renewable feedstock has a biogenic carbon content of about 100 wt-% based on the total weight of carbon (TC) in the renewable feedstcok as measured according to ASTM D6866 (2020) or EN 16640 (2017). In certain embodiments, the renewable paraffinic composition comprises recycled fossil material up to about 49 wt-% of the total weight of the renewable paraffinic composition. In certain embodiments, the renewable paraffinic composition comprises hydrocarbons, particularly paraffins preferably in the C16-C18 range, originating from waste plastics. Said waste plastics may be regarded either as recycled fossil material or recycled renewable material depending on the origin of the waste plastic.

The above mentioned oils and/or fats of the renewable feedstock typically comprise C10-C24 fatty acids and derivatives thereof, including esters of fatty acids, glycerides, i.e. glycerol esters of fatty acids. The glycerides may specifically include monoglycerides, diglycerides and triglycerides.

The oils and/or fats of the renewable feedstock may include a single kind of oil, a single kind of fat, mixtures of different oils, mixtures of different fats, mixtures of oil(s) and fat(s), fatty acids, glycerol, and/or mixtures of the afore-mentioned. Optionally, the renewable feedstock may comprise recyclable waste and/or recyclable residue, such as used cooking oil, free fatty acids, palm oil by-products or process side streams, sludge, side streams from vegetable oil processing, or a combination thereof.

The renewable paraffinic composition is a composition mainly derived from renewable raw material. In certain embodiments, the biogenic carbon content of the renewable paraffinic composition as measured according ASTM D6866 (2020) or EN 16640 (2017) is more than 50 wt-%, preferably at least 70 wt-%, more preferably at least 80 wt-%, even more preferably at least 90 wt-%, most preferably at least 99 wt-% based on the total weight of carbon in the renewable paraffinic composition. This reflects the origin of the renewable paraffinic composition.

The present disclosure also provides a direct single phase immersion cooling system comprising a bath comprising renewable paraffinic composition comprising at least 80 wt-% paraffins in the C16-C19 carbon number range based on the total weight of the renewable paraffinic composition, and an object to be cooled immersed in the renewable paraffinic composition.

The renewable paraffinic composition comprised in the bath may be a renewable paraffinic composition described in connection with the first aspect. In certain embodiments, the bath does not comprise other liquids in addition to the renewable paraffinic composition.

In certain embodiments, the direct single phase immersion cooling system comprises a heat exchanging unit; and means for circulating renewable paraffinic composition through the heat exchanging unit. The means for circulating renewable paraffinic composition may be configured to circulated renewable paraffinic composition through the heat exchanging unit continuously, in intervals, intermittently, or a combination thereof.

Alternatively, in embodiments where the renewable paraffinic composition is not circulated through a heat exchanging unit, the bath is configured to contain such an amount of the renewable paraffinic composition that it enables cooling without circulating the renewable paraffinic composition through a heat exchanging unit. Typically, such baths contain a rather large amount of renewable paraffinic composition.

In certain embodiments, circulating renewable paraffinic composition through a heat exchanging unit is performed by natural convection. Natural convection means that renewable paraffinic composition is circulated without a pump or without mixing means. Optionally, the natural convection may in some embodiments be intensified by a mixer, such as an agitator or a pump.

In certain embodiments, the heat exchanging unit is configured to cool renewable paraffinic composition that is circulated through it. In certain embodiments, the direct single phase immersion cooling system is configured to maintain the temperature of the renewable paraffinic composition comprised in the bath within a temperature range from 15° C. to 90° C., preferably from 15° C. to 75° C., more preferably from 20° C. to 65° C.

In certain embodiments, the heat exchanging unit and the means for circulating renewable paraffinic composition through the heat exchanging unit are configured to maintain the temperature of the renewable paraffinic composition comprised in the bath within a temperature range from 15° C. to 90° C., preferably from 15° C. to 75° C., more preferably from 20° C. to 65° C.

In certain embodiments, more than one objects to be cooled are immersed in the renewable paraffinic composition.

The object or objects to be cooled may be partially or completely immersed in the renewable paraffinic composition. If an object heats up unevenly, only the part or portion of the object that will heat up may in certain embodiments be immersed in the renewable paraffinic composition.

In certain embodiments, the object or objects to be cooled are electronic hardware, preferably computer hardware, more preferably a server or servers, or the object or objects to be cooled is a fuel cell or fuel cells. In certain embodiments, the bath comprises a rack or racks holding a plurality of servers.

The heat exchanging unit is not particularly limited and may be any heat exchanging unit or any heat exchanging means suitable for cooling the renewable paraffinic composition. The heat exchanging unit may be an external heat exchanging unit or a heat exchanging unit integrated to the bath. Examples of suitable heat exchanging units include a heat sink, such as metal heat sink, underground piping, piping situated outdoors, or a heat exchanging unit comprising a water cooling tower.

In certain embodiments, the heat exchanging unit comprises a heat exchanger connected to a water cooling tower, wherein the means for circulating renewable paraffinic composition through the heat exchanging unit are configured to bring renewable paraffinic composition in contact with the heat exchanger.

The means for circulating renewable paraffinic composition through the heat exchanging unit are not particularly limited and any means suitable for circulating renewable paraffinic composition through the heat exchanging unit may be used. In certain embodiments, the means for circulating renewable paraffinic composition through the heat exchanging unit comprises pipes or piping, and optionally a pump or pumps. The pipes or piping may be arranged so that renewable paraffinic composition is moved by gravity.

In certain embodiments, the direct single phase immersion cooling system comprises more than one bath or a plurality of baths, each bath comprising renewable paraffinic composition, and one or more objects to be cooled being immersed in the renewable paraffinic composition. The baths may be stacked on top of each other and/or placed next to each other.

In certain embodiments, wherein the system comprises more than one bath, the means for circulating renewable paraffinic composition through the heat exchanging unit are configured to circulate renewable paraffinic composition from each bath through the heat exchanging unit. In certain other embodiments, wherein the system comprises more than one bath, the system comprises more than one heat exchanging units and means for circulating renewable paraffinic composition through the more than one heat exchanging unit. The means for circulating renewable paraffinic composition through the more than one heat exchanging unit may be configured to circulate renewable paraffinic composition from a certain predetermined bath or certain predetermined baths through a certain predetermined heat exchanger or through certain predetermined heat exchangers. In certain embodiments, each bath has a dedicated heat exchanging unit.

The bath or baths may be so called open baths wherein the renewable paraffinic composition is in direct contact with air, or baths wherein the renewable paraffinic composition does not come into contact with air. The bath or baths may be covered e.g. with a lid or lids, either so that there remains air between the renewable paraffinic composition and the cover, or so that there is no space or air between the renewable paraffinic composition and the cover. Alternatively, the bath may be in direct contact with its surroundings and the direct single phase immersion cooling system forms an open system. In certain embodiments, the direct single phase immersion cooling system may be sealed from its environment, i.e. the direct single phase immersion cooling system may be configured so that there is no contact with surrounding air inside the system.

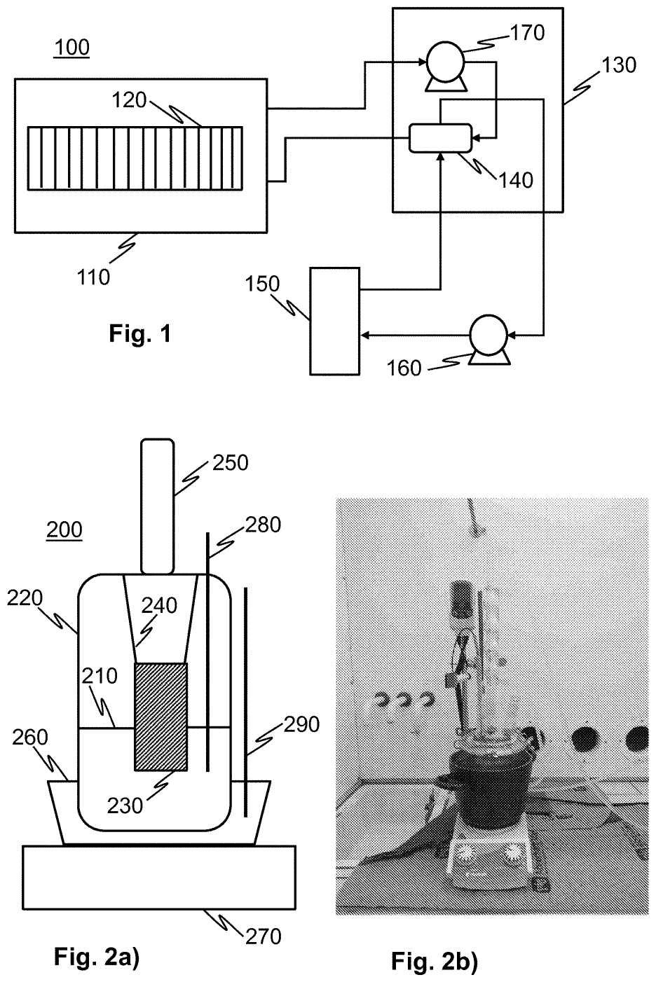

FIG. 1 shows a schematic drawing of a direct single phase immersion cooling system 100 according to an example embodiment. In the embodiment of FIG. 1, the direct single phase immersion cooling system comprises a bath 110 of renewable paraffinic composition, i.e. a vessel filled with renewable paraffinic composition to a predetermined level. A rack 120 comprising a plurality of servers has been immersed in the renewable paraffinic composition. In the embodiment of FIG. 1, the direct single phase immersion cooling system 100 further comprises a heat exchanging unit 130 comprising a heat exchanger 140 connected to a water cooling tower 150 and a water pump 160 configured to pump warm water from the heat exchanger 140 to the water cooling tower 150 and cold water from the water cooling tower 150 to the heat exchanger 140. The direct single phase immersion cooling system 100 of FIG. 1 also comprises a pump 170 configured to pump warm renewable paraffinic composition from the bath 110 to the heat exchanger 140 and cold renewable paraffinic composition from the heat exchanger 140 to the bath 110. The pump 170 configured to pump the renewable paraffinic composition from the bath 110 is equipped with a filter configured to filter the warm renewable paraffinic composition before it is passed to the heat exchanger 140. The arrows in FIG. 1 indicate the path of renewable paraffinic composition and of water within the direct single phase immersion cooling system 100. The path may be formed for example of pipes.

The present disclosure also provides a method for single phase immersion cooling comprising: providing a bath comprising a renewable paraffinic composition comprising at least 80 wt-% paraffins in the C16-C19 carbon number range based on the total weight of the renewable paraffinic composition; and immersing an object to be cooled in the renewable paraffinic composition.

The renewable paraffinic composition comprised in the bath may be a renewable paraffinic composition described in connection with the first aspect. In certain embodiments, the bath does not comprise other liquids in addition to the renewable paraffinic composition.

In certain embodiments, the method comprises circulating renewable paraffinic composition through a heat exchanging unit. Circulating renewable paraffinic composition through the heat exchanging unit may be performed continuously, in intervals, intermittently, or as a combination thereof.

In certain embodiments, circulating renewable paraffinic composition through a heat exchanging unit comprises cooling renewable paraffinic composition in the heat exchanging unit.

In certain embodiments, the method comprises maintaining the temperature of the renewable paraffinic composition comprised in the bath within a temperature range from 15° C. to 90° C., preferably from 15° C. to 75° C., more preferably from 20° C. to 65° C., preferably by circulating renewable paraffinic composition through the heat exchanging unit.

In certain embodiments, circulating renewable paraffinic composition through a heat exchanging unit comprises conducting renewable paraffinic composition through a pipe or piping from the bath to the heat exchanging unit and from the heat exchanging unit to the bath. In certain embodiments, circulating renewable paraffinic composition through a heat exchanging unit comprises pumping renewable paraffinic composition from the bath to the heat exchanging unit and from the heat exchanging unit to the bath.

In certain embodiments, the method comprises immersing more than one objects to be cooled in the renewable paraffinic composition. The object or objects to be cooled may be at least partially or completely immersed in the renewable paraffinic composition. The object or objects to be cooled immersed in the renewable paraffinic composition may be any object or objects described in connection with the first or second aspect, such as electronic hardware, preferably computer hardware, more preferably a server or servers, or a rack holding a server or a plurality of serves, or a fuel cell or fuel cells.

In certain embodiments, the method comprises providing a plurality of baths comprising renewable paraffinic composition, and immersing in each bath an object or objects to be cooled in the renewable paraffinic composition, and circulating renewable paraffinic composition through a heat exchanging unit or through more than one heat exchanging units. Renewable paraffinic composition of a certain predetermined bath or certain predetermined baths may be circulated through a certain predetermined heat exchanging unit or certain predetermined heat exchanging units. In certain embodiments, renewable paraffinic composition is circulated from each bath to a heat exchanging unit dedicated for that bath.

The highly efficient cooling solution described in the present disclosure allows increasing data output, without the temperature being a limiting factor. While sometimes it may be desired to keep the data output constant, in which case the present solution can provide decreased operation temperature, oftentimes it is desired to increase the data output and let the operating temperature rise while utilising the excess heat e.g. in district heating. The present solution supports both operation modes.

### EXAMPLES

### Example 1

### Renewable Paraffinic Compositions

Carbon number distribution as well as physical and chemical properties of two examples of renewable paraffinic compositions, namely compositions P1 and P2, are shown below.

Table 1 summarises the carbon number distribution of composition P1, and Table 2 summarises physical and chemical properties of composition P1. Table 3 summarises the carbon number distribution of composition P2, and Table 4 summarises physical and chemical properties of composition P2.

The example composition P1 was produced by hydrodeoxygenation and isomerisation of renewable feedstock as explained above. Accordingly, the biogenic carbon content of P1 was 100% (ASTM D6866 (2020) or EN 16640 (2017)). The isomerisation step was followed by a distillation step to recover a hydrocarbon composition having an initial boiling point (IBP) of 275.4° C. and a final boiling point (FBP) of 321.0° C. The carbon number distribution of composition P1 is presented in Table 1. The composition P1 comprised 96.05% i-paraffins and 3.95% n-paraffins. 95.71 wt-% of all paraffins were in the C16-C19 range. The amount of C15 and lighter paraffins was 0.69 wt-% and of C20 and heavier paraffins was 3.59 wt-%. Biodegradability of composition P1 was assessed according to OECD Test Guideline 301 F, and the composition was found readily biodegradable.

TABLE 1
Carbon number distribution of renewable
paraffinic composition P1.

| Carbon | | | |
|---|---|---|---|
| number | i-paraffins | n-paraffins | Total paraffins |
| 3 | 0.00 | 0.00 | 0.00 |
| 4 | 0.00 | 0.00 | 0.00 |
| 5 | 0.00 | 0.00 | 0.00 |
| 6 | 0.00 | 0.00 | 0.00 |
| 7 | 0.05 | 0.03 | 0.08 |
| 8 | 0.08 | 0.02 | 0.10 |
| 9 | 0.04 | 0.01 | 0.05 |
| 10 | 0.03 | 0.00 | 0.03 |
| 11 | 0.02 | 0.00 | 0.02 |
| 12 | 0.01 | 0.00 | 0.01 |
| 13 | 0.01 | 0.00 | 0.01 |
| 14 | 0.01 | 0.00 | 0.01 |
| 15 | 0.30 | 0.08 | 0.38 |
| 16 | 4.01 | 0.12 | 4.12 |
| 17 | 33.31 | 1.91 | 3.22 |
| 18 | 51.62 | 1.62 | 5.24 |
| 19 | 3.05 | 0.08 | 3.13 |
| 20 | 1.44 | 0.04 | 1.48 |
| 21 | 0.47 | 0.02 | 0.49 |
| 22 | 0.24 | 0.01 | 0.25 |
| 23 | 0.12 | 0.00 | 0.13 |
| 24 | 0.07 | 0.00 | 0.07 |
| 25-29 | 0.78 | 0.00 | 0.78 |
| 30-36 | 0.39 | 0.00 | 0.39 |
| >C36 | 0.00 | 0.00 | 0.00 |
| Total | 96.05 | 3.95 | 100.00 |
| paraffins | | | |

TABLE 2
Physical and chemical properties of
renewable paraffinic composition P1.

| Method | Property | Unit | |
|---|---|---|---|
| PHYSICAL & CHEMICAL PROPERTIES | | | |
| ENISO12185 | DENSITY | kg/m3 | 787.6 |
| ENISO12185 | DENS20° C. | kg/m3 | 784.1 |
| ISO2049 | COLOUR | | L 0.5 |
| ASTMD4176-1 | APPEARANCE | | CLEAR |
| ENISO2592 | Flash point-COC | ° C. | 146 |
| ENISO2719 | Flash point-PM | ° C. | 125 |
| EN14522 | AUTOIGNITION TEMP | ° C. | 211 |
| IP529 | Freezing point -AUT | ° C. | −26 |
| ASTMD7689 | Cloud point-EXACT | ° C. | −31 |
| ASTMD5950 | Pour point-ISL | ° C. | −48 |
| ENISO20846 | SULPHUR | mg/kg | <1 |
| ENISO12937 | WATER | mg/kg | 18 |
| ENISO2160 | Copper Corrosion | no | 1a |
| | 3H/50° C. | | |
| EN12662 | SEDIMENT-TOT | mg/kg | 6.5 |
| ISO2977 | ANILINEPOINT | ° C. | 100.3 |
| ASTMD1133 | KAURIBUTANOL | | 18.5 |
| ASTMD1218 | Refractive index-20 | | 1.4395 |
| UOP495 | AROMATICS | wt-% | 0.37 |
| ASTMD3242 | ACIDITY-TAN | mg | 0.001 |
| | | KOH/g | |
| ISO6297 | CONDUCTIVITY at | pS/m | 161 |
| | 22° C. | | |
| IP387 | FBT | | 6.83 |
| NM490A | N-PARAFFINS | wt-% | 3.95 |
| ASTMD5800-B | NOACK150 | wt-% | 8.6 |
| ASTMD971M | SURFACE-TENSION | mN/m | 27 |
| ASTMD971 | INTERFAC-TENSION | mN/m | 46 |
| ASTMD971 | TEMPERATURE | ° C. | 25 |

VISCOSITY

| | | | |
|---|---|---|---|
| ENISO3104 | VISCO100C | mm2/s | 1 |
| ENISO3104 | VISCO40C | mm2/s | 4 |
| ENISO3104 | VISCO20C | mm2/s | 6 |
| ENISO3104 | VISCO10° C. | mm2/s | 9 |
| ENISO3104 | VISCO-0C | mm2/s | 12 |
| ENISO3104 | VISCO-10 | mm2/s | 18 |
| ENISO3104 | VISCO-20C | mm2/s | 30 |
| ENISO3104 | VISCO-30C | mm2/s | 55 |

METALS

| | | | |
|---|---|---|---|
| NM534 | BORON | mg/kg | <1 |
| NM534 | SODIUM | mg/kg | <0.10 |
| NM534 | MAGNESIUM | mg/kg | <0.10 |
| NMS34 | ALUMINIUM | mg/kg | <0.10 |
| NM534 | SILICON | mg/kg | 0.19 |
| NM534 | PHOSPHOROUS | mg/kg | <0.10 |
| NM534 | POTASSIUM | mg/kg | 0.23 |
| NM534 | CALCIUM | mg/kg | <0.10 |
| NM534 | TITANIUM | mg/kg | <0.10 |
| NM534 | VANADINIUM | mg/kg | <0.10 |
| NM534 | CHROMIUM | mg/kg | <0.10 |
| NM534 | MANGANESE | mg/kg | <0.10 |
| NM534 | IRON | mg/kg | <0.10 |
| NM534 | NICKEL | mg/kg | <0.10 |
| NM534 | COPPER | mg/kg | <0.10 |
| NM534 | ZINC | mg/kg | <0.10 |
| NM534 | MOLYBDENIUM | mg/kg | <0.10 |
| NM534 | CADMIUM | mg/kg | <0.10 |
| NM534 | TIN | mg/kg | <0.10 |
| NM534 | BARIUM | mg/kg | <0.10 |
| NM534 | LEAD | mg/kg | <0.10 |

DISTILLATION

| | | | |
|---|---|---|---|
| ENISO3405 | DIS-IBP | ° C. | 275.4 |
| ENISO3405 | DIS-05 | ° C. | 291.7 |
| ENISO3405 | DIS-10 | ° C. | 292.2 |
| ENISO3405 | DIS-20 | ° C. | 292.8 |
| ENISO3405 | DIS-30 | ° C. | 293.2 |
| ENISO3405 | DIS-40 | ° C. | 293.7 |
| ENISO3405 | DIS-50 | ° C. | 294.2 |
| ENISO3405 | DIS-60 | ° C. | 294.7 |
| ENISO3405 | DIS-70 | ° C. | 295.5 |
| ENISO3405 | DIS-80 | ° C. | 296.7 |
| ENISO3405 | DIS-90 | ° C. | 299.4 |
| ENISO3405 | DIS-95 | ° C. | 306.5 |
| ENISO3405 | DIS-FBP | ° C. | 321 |
| ENISO3405 | DIS-RECOVERY | vol-% | 97.2 |

The example composition P2 was produced though distillation of composition P1 to recover a hydrocarbon composition having an initial boiling point (IBP) 283.5° C. and final boiling point (FBP) 298.5° C. The carbon number distribution of composition P2 is presented in Table 3. The biogenic carbon content of P2 was thus also 100% (ASTM D6866 (2020) or EN 16640 (2017)). The carbon number distribution of composition P2 is presented in Table 3. Composition P2 comprised 96.75% paraffins and 3.25% n-paraffins. 99.08 wt-% of all the paraffins were in the C16-C19 range. The ratio of the amount of C18 i-paraffins to the amount of C18 n-paraffins is 45.52 based on the weight of the C18 i-paraffins and the weight of the C18 n-paraffins in composition P2. Composition P2 comprised 0.31 wt-% C15 and lighter paraffins and 0.62 wt-% C20 and heavier paraffins. Further, composition P2 comprised more than 37 wt-% C17 paraffins.

Table 4 summarizes physical and chemical properties of composition P2. As can be seen from Table 4 composition P2 comprises very little or is essentially free from metals, which strengthens the dielectric behaviour of composition P2. As can be seen from Table 4, the (electrical) conductivity of composition P2 was less than 1 pS/m. In other words, composition P2 is particularly well suited to be used as a coolant liquid for direct single phase immersion cooling of electronic hardware, such as computer hardware. Biodegradability of composition P2 was assessed according to OECD Test Guideline 301 F, and the composition was found readily biodegradable.

TABLE 3
Carbon number distribution of renewable
paraffinic composition P2.

| Carbon | | | Total |
|---|---|---|---|
| number | i-paraffins | n-paraffins | paraffins |
| 3 | 0.00 | 0.00 | 0.00 |
| Ff | 0.00 | 0.00 | 0.00 |
| 5 | 0.00 | 0.00 | 0.00 |
| 6 | 0.00 | 0.00 | 0.00 |
| 7 | 0.00 | 0.00 | 0.00 |
| 8 | 0.00 | 0.00 | 0.00 |
| 9 | 0.00 | 0.00 | 0.00 |
| 10 | 0.00 | 0.00 | 0.00 |
| 11 | 0.00 | 0.00 | 0.00 |
| 12 | 0.00 | 0.00 | 0.00 |
| 13 | 0.00 | 0.00 | 0.00 |
| 14 | 0.01 | 0.00 | 0.02 |
| 15 | 0.22 | 0.08 | 0.29 |
| 16 | 3.66 | 0.42 | 4.08 |
| 17 | 37.42 | 1.51 | 38.93 |
| 18 | 53.27 | 1.17 | 54.44 |
| 19 | 1.58 | 0.04 | 1.63 |
| 20 | 0.45 | 0.03 | 0.48 |
| 21 | 0.10 | 0.00 | 0.10 |
| 22 | 0.03 | 0.00 | 0.04 |
| 23 | 0.00 | 0.00 | 0.00 |
| 24 | 0.00 | 0.00 | 0.00 |
| 25-29 | 0.00 | 0.00 | 0.00 |
| 30-36 | 0.00 | 0.00 | 0.00 |
| >C36 | 0.00 | 0.00 | 0.00 |
| Total | 96.75 | 3.25 | 100.00 |
| paraffins | | | |

TABLE 4
Physical and chemical properties of renewable paraffinic composition P2.
PHYSICAL & CHEMICAL PROPERTIES

| | | | |
|---|---|---|---|
| ENISO12185 | DENSITY | kg/m3 | 786.6 |
| ENISO12185 | DENS20° C. | kg/m3 | 783.2 |
| ISO2049 | COLOUR | | L 0.5 |
| ASTMD4176-1 | APPEARANCE | | C&B |
| ENISO2592 | Flash point-COC | ° C. | 149 |
| ENISO2719 | Flash point-PM | ° C. | 145 |
| EN14522 | AUTOIGNITION TEMP | ° C. | 211 |
| IP529 | Freezing point -AUT | ° C. | −22 |
| ASTMD7689 | Cloud point-EXACT | ° C. | −34 |
| ASTMD5950 | Pour point-ISL | ° C. | −69 |
| ENISO20846 | SULPHUR | mg/kg | <1 |
| ENISO12937 | WATER | mg/kg | 17 |
| ENISO2160 | Copper Corrosion | no | 1a |
| | 3H/50° C. | | |
| EN12662 | SEDIMENT-TOT | mg/kg | |
| ISO2977 | ANILINEPOINT | ° C. | 99.9 |
| ASTMD1133 | KAURIBUTANOL | | 18.5 |
| ASTMD1218 | Refractive index-20 | | 1.4391 |
| UOP498 | AROMATICS | wt-% | 0.04 |
| ASTMD3242 | ACIDITY-TAN | mg | <0.001 |
| | | KOH/g | |
| ISO6297 | CONDUCTIVITY at | | <1 |
| | 22° C. | | |
| IP387 | FBT | | 1.01 |
| NM490A | N-PARAFFINS | wt-% | 3.25 |
| ASTM05800-B | NOACK150 | wt-% | 8.4 |
| ASTMD971M | SURFACE-TENSION | mN/m | 27 |
| ASTMD971 | INTERFAC-TENSION | mN/m | 51 |
| ASTMD971 | TEMPERATURE | ° C. | 25 |

VISCOSITY

| | | | |
|---|---|---|---|
| ENISO3104 | VISCO100C | mm2/s | 1 |
| ENISO3104 | VISCO40C | mm2/s | 4 |
| ENISO3104 | VISCO20C | mm2/s | 6 |
| ENISO3104 | VISCO10° C. | mm2/s | 8 |
| ENISO3104 | VISCO-0C | mm2/s | 12 |
| ENISO3104 | VISCO-10 | mm2/s | 18 |
| ENISO3104 | VISCO-20C | mm2/s | 29 |
| ENISO3104 | VISCO-30C | mm2/s | 52 |

METALS

| | | | |
|---|---|---|---|
| NM534 | BORON | mg/kg | <1 |
| NM534 | SODIUM | mg/kg | <0.10 |
| NM534 | MAGNESIUM | mg/kg | <0.10 |
| NM534 | ALUMINIUM | mg/kg | <0.10 |
| NM534 | SILICON | mg/kg | <0.10 |
| NM534 | PHOSPHOROUS | mg/kg | <0.10 |
| NM534 | POTASSIUM | mg/kg | <0.10 |
| NM534 | CALCIUM | mg/kg | <0.10 |
| NM534 | TITANIUM | mg/kg | <0.10 |
| NM534 | VANADINIUM | mg/kg | <0.10 |
| NM534 | CHROMIUM | mg/kg | <0.10 |
| NM534 | MANGANESE | mg/kg | <0.10 |
| NM534 | IRON | mg/kg | <0.10 |
| NM534 | NICKEL | mg/kg | <0.10 |
| NM534 | COPPER | mg/kg | <0.10 |
| NM534 | ZINC | mg/kg | <0.10 |
| NM534 | MOLYBDENIUM | mg/kg | <0.10 |
| NM534 | CADMIUM | mg/kg | <0.10 |
| NM534 | TIN | mg/kg | <0.10 |
| NM534 | BARIUM | mg/kg | <0.10 |
| NM534 | LEAD | mg/kg | <0.10 |

DISTILLATION

| | | | |
|---|---|---|---|
| ENISO3405 | DIS-IBP | ° C. | 283.5 |
| ENISO3405 | DIS-05 | ° C. | 291.1 |
| ENISO3405 | DIS-10 | ° C. | 291.5 |
| ENISO3405 | DIS-20 | ° C. | 291.9 |
| ENISO3405 | DIS-30 | ° C. | 292.2 |
| ENISO3405 | DIS-40 | ° C. | 292.3 |
| ENISO3405 | DIS-50 | ° C. | 292.6 |
| ENISO3405 | DIS-60 | ° C. | 293.1 |
| ENISO3405 | DIS-70 | ° C. | 293.6 |
| ENISO3405 | DIS-80 | ° C. | 294.2 |
| ENISO3405 | DIS-90 | ° C. | 295.2 |
| ENISO3405 | DIS-95 | ° C. | 296.4 |
| ENISO3405 | DIS-FBP | ° C. | 298.5 |
| ENISO3405 | DIS-RECOVERY | vol-% | 98 |

TABLE 4.1
Properties of renewable paraffinic composition
P2 over a temperature range from 10° C.
to 85° C. Nd denotes not determined.

| | Property | | | |
|---|---|---|---|---|
| | | Kinematic | Electrical | Specific heat |
| | Density | viscosity | resistivity | capacity |
| | Test method | | | |
| | ASTM D4052- | ASTM | ASTM D1169- | ASTM E1269- |
| | 18a | D445-21 | 19a | 11(2018) |
| Temper- | Unit | | | |
| ature | kg/m³ | mm²/s | Ω · cm | kJ/(kg · K) |
| 10° C. | 790 | 8.43 | nd | 2.06 |
| 25° C. | 779 | 5.24 | 9.38E+15 | 2.17 |
| 40° C. | 770 | 3.74 | 5.29E+15 | 2.27 |
| 55° C. | 760 | 2.72 | 2.62E+15 | 2.37 |
| 70° C. | nd | nd | 1.16E+15 | nd |
| 85° C. | 740 | 1.72 | 5.31E+14 | 2.63 |

### Example 2

### Immersion Tests

The effect of immersion liquid (coolant liquid) upon computer hardware was studied.

A computer motherboard was cut into pieces and the pieces were partially immersed into renewable paraffinic composition corresponding to the renewable paraffinic composition P2 of Example 1 (P2) and Fluorinert™ FC-40 commercially available from 3M™, respectively, at different temperatures as shown in Table 5.

TABLE 5
Test conditions for immersion tests
T1-T6. RT is room temperature.

| | | Temperature | Time | Oil bath |
|---|---|---|---|---|
| | Liquid | (° C.) | (h) | stirring (rpm) |
| T1 | P2 | 20 | 24 | 100 |
| T2 | P2 | 50 | 24 | 250 |
| T3 | P2 | RT/50/85/RT | 4/24/23/3 | 250 |
| T4 | FC-40 | 20 | 24 | 100 |
| T5 | FC-40 | 50 | 24 | 250 |
| T6 | FC-40 | RT/50/85/RT | 4/24/23/3 | 250 |

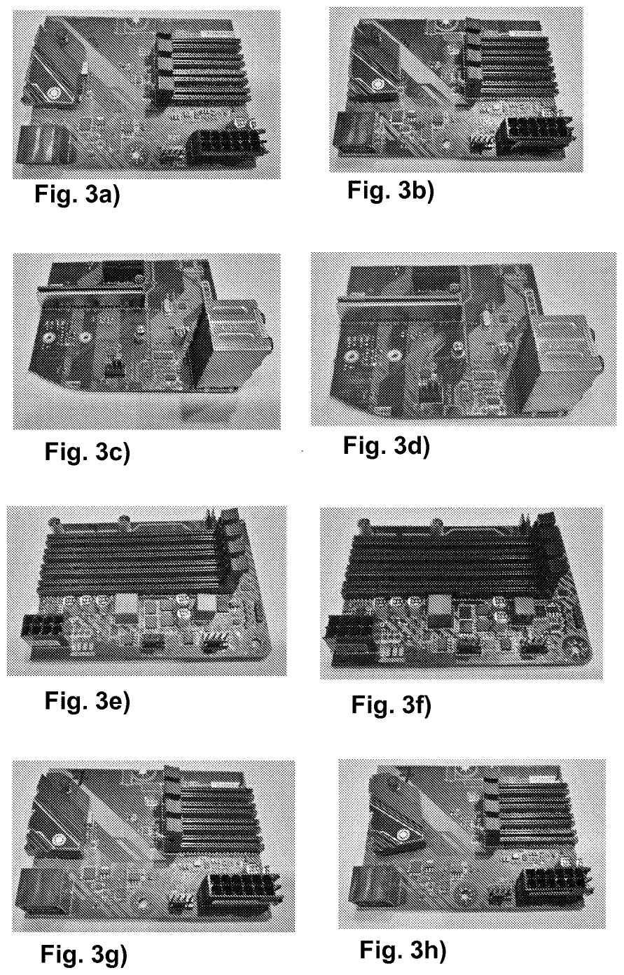

FIG. 2a) shows a schematic drawing of the test setup 200. Immersion liquid 210 was poured into a flange pot 220 and a piece of the cut mother board 230 was partially immersed into the liquid 210 by suspending it from the top part of the flange pot with wire or thread 240. A water condenser 250 was connected to the flange pot lid. The flange pot 220 was placed into an oil bath 260 on a hot plate 270 and the oil bath was stirred with a magnetic stirrer. The temperatures of the immersion liquid 210 and the oil bath 260 were monitored with respective thermometers 280, 290. FIG. 2b) shows a photograph of the test setup in use.

In tests T1, T2, T4, and T5 the temperature was kept constant at either 20° C. or 50° C. and the immersion time was approximately 24 h. In tests T3 and T6 the temperature was cycled during immersion from room temperature to 50° C., from 50° C. to 85° C., and from 85° C. back to room temperature. In tests T3 and T6 the immersion time at room temperature was approximately 4 h, at 50° C. approximately 24 h, at 85° C. approximately 23 h, and again at room temperature approximately 3 h. At the end of the predetermined immersion time, the motherboard piece was taken out from the immersion liquid and flange pot and dried with pressurized air: The motherboard piece was then left to dry in air overnight.

The motherboard pieces were characterized by measuring their mass, circuit resistance and capacitance before and after the immersion, once the pieces had dried overnight. The results of the characterizations are shown in Table 6 below. Circuit resistance was measured on the same unit design (a plug pin) before and after immersion and the value obtained was recorded after giving three consistent readings.

TABLE 6
Component characteristics before and after immersion, tests T1-T6. Change
denotes relative change using value before immersion as reference.

| | | | | Circuit resistance (kΩ) | | | Capacitance (μF) | | |
|---|---|---|---|---|---|---|---|---|---|
| | Mass (g) | | | ASTM F1680 | | | ASTM F1663 | | |
| Test | Before | After | Change/% | Before | After | Change/% | Before | After | Change/% |
| T1 | 63.856 | 64.153 | +0.47 | 22.22 | 22.22 | 0 | 72.7 | 73.1 | 0.55 |
| T2 | 65.403 | 65.475 | +0.11 | 350.60 | 351.70 | +0.31 | 20.7 | 20.6 | −0.48 |
| T3 | 60.963 | 59.873 | −1.78 | 12.67 | 12.67 | 0 | 90.9 | 93.1 | 2.42 |
| T4 | 64.090 | 64.452 | +0.56 | 22.28 | 22.28 | 0 | 74.5 | 73.3 | −1.61 |
| T5 | 65.699 | 65.920 | 0.34 | 361.00 | 360.80 | −0.06 | 20.4 | 19.6 | −3.92 |
| T6 | 59.917 | 59.873 | −0.07 | 12.64 | 12.64 | 0 | 91.9 | 92 | +0.11 |

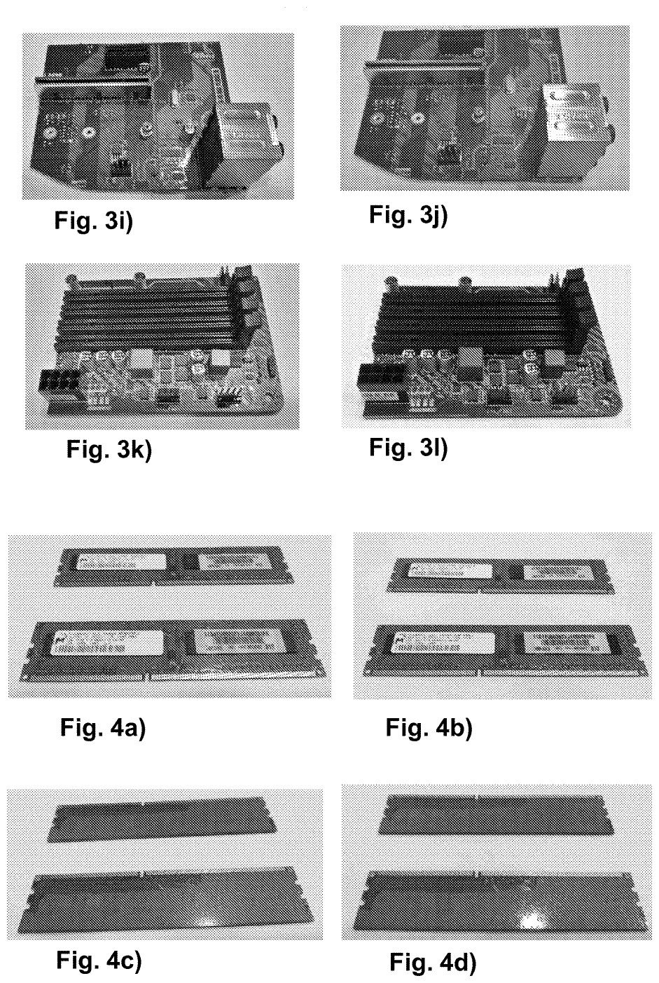

The motherboard pieces were also visually inspected before and after immersion and their thickness were measured before and after immersion to assess possible swelling. Photographs of the motherboard pieces before and after immersion are shown in FIGS. 3a)-3l). FIGS. 3a) and 3b) show the motherboard piece before and after immersion according to T1, respectively. FIGS. 3c) and 3d) shows the motherboard piece before and after immersion according to T2, respectively. FIGS. 3e) and 3f) shows the motherboard piece before and after immersion according to T3, respectively. FIGS. 3g) and 3h) shows the motherboard piece before and after immersion according to T4, respectively. FIGS. 3i) and 3j) shows the motherboard piece before and after immersion according to T5, respectively. FIGS. 3k) and 3bl) shows the motherboard piece before and after immersion according to T6, respectively.

In each of T1-T6, the immersion did not cause any delamination or any swelling, and the text on the motherboard pieces did not fade during immersion. Once the motherboard pieces had dried overnight, only small amounts of immersion liquid residue could be identified on the motherboard pieces. Also, in each of T1-T6 the immersion did not significantly affect the mass, circuit resistance or capacitance of the motherboard pieces, as can be seen from Table 6. The essentially negligible change of the circuit resistance indicates that coolant liquids did not adhere to the pins, and that metals did not leach into the coolant liquids. Surprisingly, immersion in P2 did not affect the motherboard pieces and P2 performed as well as the commercially available coolant liquid FC-40 for direct single phase immersion cooling.

The coolant liquids of T1-T6 were characterized by measuring their density and refractive index before and after immersion. The results are shown in Table 7 below. The coolant liquids were also visually inspected before and after immersion.

TABLE 7
Coolant liquid characteristics before and after
immersion tests T1-T6. Change denotes relative
change using value before immersion as reference.

| | Density kg/m³ | | | Refractive Index | | |
|---|---|---|---|---|---|---|
| Test | Before | After | Change | Before | After | Change |
| T1 | 786.65 | 786.66 | 0% | 1.439 | 1.439 | 0% |
| T2 | 786.65 | 786.67 | 0% | 1.439 | 1.439 | 0% |
| T3 | 786.65 | 786.67 | 0% | 1.439 | 1.439 | 0% |
| T4 | 1892.5 | 1892.2 | −0.01% | Out of | Out of | N/A |
| | | | | range | range | |
| T5 | 1892.5 | 1892.4 | 0% | Out of | Out of | N/A |
| | | | | range | range | |
| T6 | 1892.5 | 1894.8 | 0.12% | Out of | Out of | N/A |
| | | | | range | range | |

The densities of P2 and FC-40 were not affected in any of test T1-T4. A change in density would indicate notable change in the composition of the coolant liquid, which was not seen in any of tests T1-T6. P2 has a significantly lower density compared to FC-40, which is advantageous in terms of energy required to circulate the liquid. A lower density also reduces the weight of the immersion bath, which is beneficial e.g. if baths are to be stacked on top of each other. Also, due to the lower density, P2 exerts a lower buoyant force on an object immersed therein compared to FC-40. This is especially beneficial for direct single phase immersion cooling of very light objects or objects having a shape that highly affects the buoyant force. Further, the refractive index of P2 remained unchanged. The refractive index of FC-40 could not be measured as it was out of measuring range. Without being bound to any theory, it is believed that the refractive index of FC-40 is too low to be measured. The measurement of refractive index is very sensitive and thus the refractive index can be used to monitor changes, such as leaching or decomposition, in the coolant liquid. An advantage of being able to measure the refractive index is thus that it allows monitoring easily, online and in real time, changes in the coolant liquid and allows easy and prompt identification of a need to change the immersion liquid or to make corrective maintenance of the direct single phase immersion cooling system.

Both P2 and FC-40 were clear liquids and their appearance did not change during any of the tests T1-T3 and T4-T6, respectively.

It can thus be concluded that no dissolution of the motherboard pieces appeared. P2 did not dissolve any of the sensitive structures or markings of the motherboard pieces and was as compatible with the computer hardware as the commercially available coolant liquid FC-40 for direct single phase immersion cooling. To confirm that no leaching occurred during immersion, elemental analysis on the coolant liquids was performed after each of T1-T6. Fresh, unused P2 and FC-40 were used as references. The results of the elemental analysis are shown in Table 9 below.

TABLE 9
Results from elemental analysis of coolant liquids after each
of T1-T6. Fresh P2 and FC-40 were used as references.

| | Ref | Ref | Test 1 | Test 2 | Test 3 | Test 4 | Test5 | Test 6 |
|---|---|---|---|---|---|---|---|---|
| Coolant | P2 | FC-40 | P2 | P2 | P2 | FC-40 | FC-40 | FC-40 |
| T (° C.) | RT | RT | RT | 50 | RT/50/85/RT | RT | 50 | RT/50/85/RT |
| Boron | <1 | <0.120 | <1 | <0.120 | <1 | <0.120 | <0.120 | <0.120 |
| Sodium | <0.10 | <0.280 | 0.21 | <0.280 | 0.12 | <0.280 | <0.280 | <0.280 |
| Magnesium | <0.10 | <0.110 | <0.10 | <0.110 | <0.10 | <0.110 | <0.110 | <0.110 |
| Aluminium | <0.10 | <0.185 | <0.10 | <0.185 | <0.10 | <0.185 | <0.185 | <0.185 |
| Silicon | <0.10 | 5.2 | 0.88 | 0.94 | 0.36 | 1.3 | 1.3 | 0.46 |
| Phosphorous | <0.10 | <0.250 | <0.10 | <0.250 | <0.10 | <0.250 | 0.4 | <0.250 |
| Potassium | <0.10 | 0.74 | <0.10 | <0.720 | <0.10 | <0.720 | <0.720 | <0.720 |
| Calcium | <0.10 | <0.690 | <0.10 | <0.690 | <0.10 | <0.690 | <0.690 | <0.690 |
| Titanium | <0.10 | <0.050 | <0.10 | <0.050 | <0.10 | <0.050 | <0.050 | <0.050 |
| Vanadinium | <0.10 | <0.010 | <0.10 | <0.010 | <0.10 | <0.010 | <0.010 | <0.010 |
| Chromium | <0.10 | <0.100 | <0.10 | <0.100 | <0.10 | <0.100 | <0.100 | <0.100 |
| Manganese | <0.10 | <0.010 | <0.10 | <0.010 | <0.10 | <0.010 | <0.010 | <0.010 |
| Iron | <0.10 | <0.370 | <0.10 | <0.370 | <0.10 | <0.370 | <0.370 | <0.370 |
| Nickel | <0.10 | <0.210 | <0.10 | <0.210 | <0.10 | <0.210 | <0.210 | <0.210 |
| Copper | <0.10 | <0.055 | <0.10 | <0.055 | <0.10 | <0.055 | <0.055 | <0.055 |
| Zinc | <0.10 | <0.170 | <0.10 | <0.170 | <0.10 | <0.170 | <0.170 | <0.170 |
| Molybdenium | <0.10 | <0.020 | <0.10 | <0.020 | <0.10 | <0.020 | <0.020 | <0.020 |
| Cadmium | <0.10 | <0.010 | <0.10 | <0.010 | <0.10 | <0.010 | <0.010 | <0.010 |
| Tin | <0.10 | <0.025 | <0.10 | 0.026 | 0.13 | <0.025 | <0.025 | <0.025 |
| Barium | <0.10 | <0.005 | <0.10 | <0.005 | <0.10 | <0.005 | <0.005 | <0.005 |
| Lead | <0.10 | <0.120 | <0.10 | <0.120 | <0.10 | <0.120 | <0.120 | <0.120 |

As can be seen from Table 9, there is very little leaching of material into the coolant liquids. Regarding P2, there is an expected increase in sodium and silicon from the glass reaction vessel, however, there is no sign of leaching from any motherboard piece during immersion. As can be seen from Table 9, the immersions caused very little change in the elemental composition of FC-40.

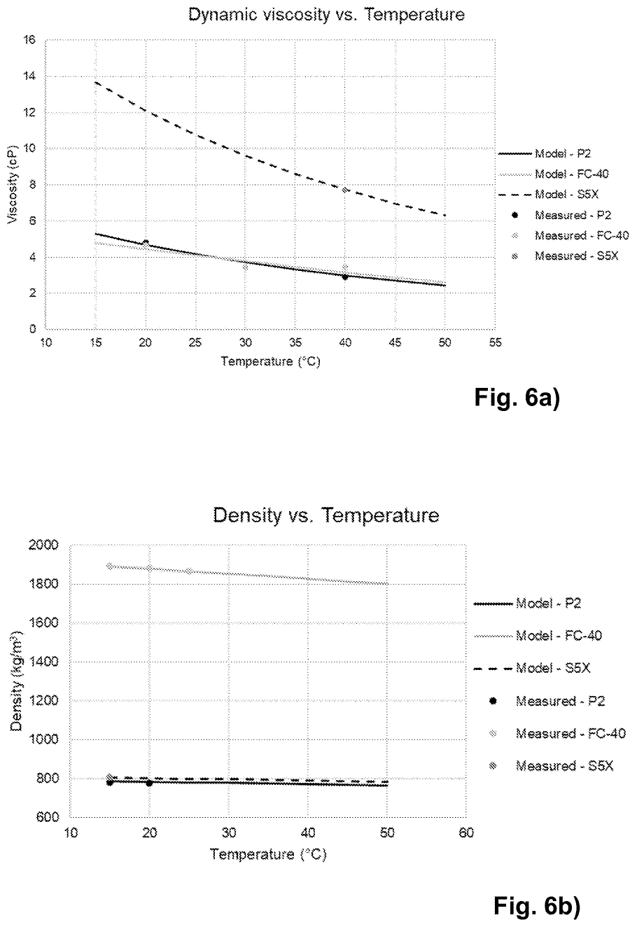

FIG. 5 shows the distillation curves of P2 and of FC-40, respectively. The black curve denotes P2 and the grey curve denotes FC-40. It can be seen from FIG. 5 that P2 boiled at higher temperatures compared to FC-40 and that the boiling point range of P2 was significantly narrower than that of FC-40. Accordingly, P2 contains less volatile compounds and remains in liquid phase at higher temperatures of operation compared to FC-40. This improves the safety of P2 and allows its used in direct single phase immersion cooling systems open to their surroundings. As FC-40 is a source of greenhouse gas, measures has to be taken to prevent its release from the direct single phase immersion system to the surroundings. Compared to FC-40, P2 provides overall a more sustainable, environmentally and climate friendly alternative. Opposite to FC-40, P2 may be obtained from renewable feedstock, it does not release greenhouse gases, it is not persistent in nature but is instead classified as readily biodegradable according to OECD Test Guideline 301 F, and it may have value added use in refineries once it has served as an coolant liquid for direct single phase immersion cooling.

### Example 3

### Usability of Computer Hardware After Immersion

RAM boards were removed from a desktop computer and immersed in P2 at 50° C. for 83 h. The test set-up described in connection with Example 2 and illustrated by FIGS. 2a) and 2b) was used. Stirring of the oil bath was set to 250 rpm.

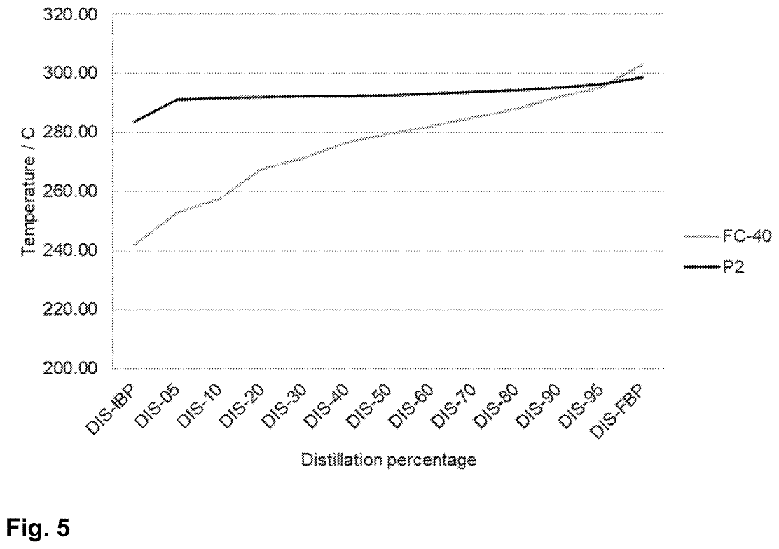

Photographs of the RAM boars before immersion are shown in FIGS. 4a) and 4c), and after immersion in FIGS. 4b) and 4d). Upon visual inspection of the RAM boards before and after immersion it was concluded that the RAM boards remained visually unchanged and no significant residues of P2 on the boards was identified after drying. The RAM boards were reinserted into the desktop computer. Upon startup of the computer, the system loaded without problems and the BIOS was accessed and evaluated normally. Accordingly, the immersion in P2 at 50° C. for 83 h did not result in any detrimental effects, and the computer with the reinserted RAM boards worked as before.

### Example 4

### Data Center Cooling Simulations

Three different coolant liquids, namely a renewable paraffinic composition corresponding to the renewable paraffinic composition P2 of Example 1 (P2), Fluorinert™ FC-40 (perfluorotri-n-butylamine) commercially available from 3M™, and S5X (fossil based alkanes) commercially available from Royal Dutch Shell, were compared in a data center cooling simulation study.

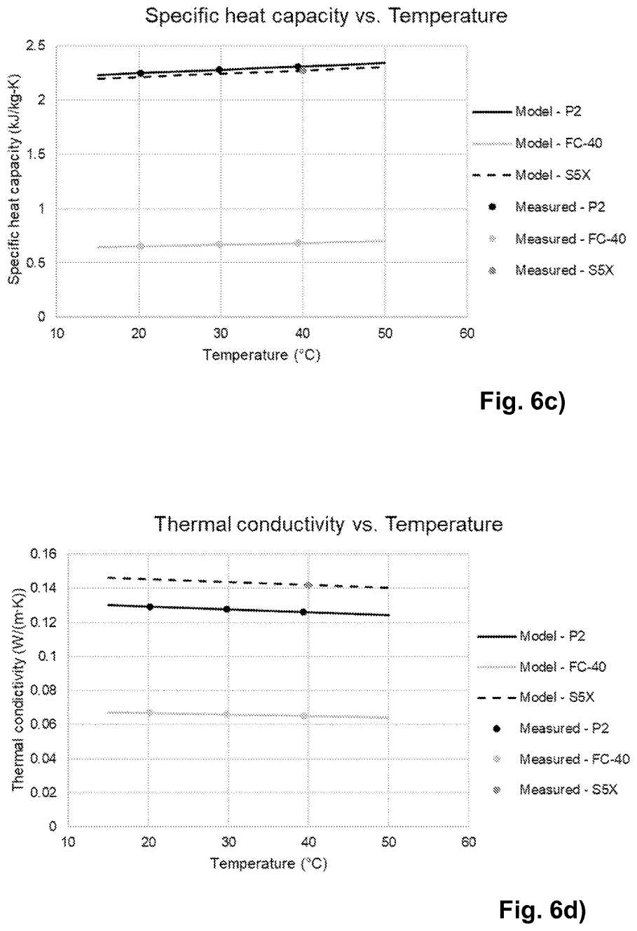

Properties of the coolant liquids P2, FC-40, and S5X are shown in FIGS. 6a) to 6d) as a function of temperature (T ranging from 15° C. to 50° C.). As seen in FIG. 6 a), P2 has a low dynamic viscosity which decreases even further as the temperature increases. A low viscosity improves the heat exchange between the object to be cooled and the coolant liquid as the coolant liquid may be circulated through all components of an object to be cooled, reaching even very tiny cavities thereof. As seen in FIGS. 6b), 6c), and 6 d), respectively, the density, specific heat capacity (massic heat capacity), and thermal conductivity of P2 remains relatively constant within the temperature range from 15° C. to 50° C. The relatively constant density, specific heat capacity, and thermal conductivity improve predictability and hence reliability of P2 as a coolant liquid. It can be deduced from FIGS. 6a) to 6d) that P2 may be used also at higher temperatures of the temperature range which allows for side applications like district heating to be realistically considered.

The simulations were conducted using EDR (rigorous heat exchange model). A rack of 42 servers was simulated as a heat exchanger and a heat exchanger area of 33 m² was estimated from dimensions of a server chassis by multiplying the are of one server chassis by 42 (the dimensions of one server chassis were 0.71 m×0.483 m×0.0444 m). The system of a rack of 42 servers immersed in the respective coolant liquid was in the simulation study modelled by a shell and tube heat exchanger where steam was used in the tube side (hot side) to provide an even temperature profile and the respective coolant liquid was used on the shell side.

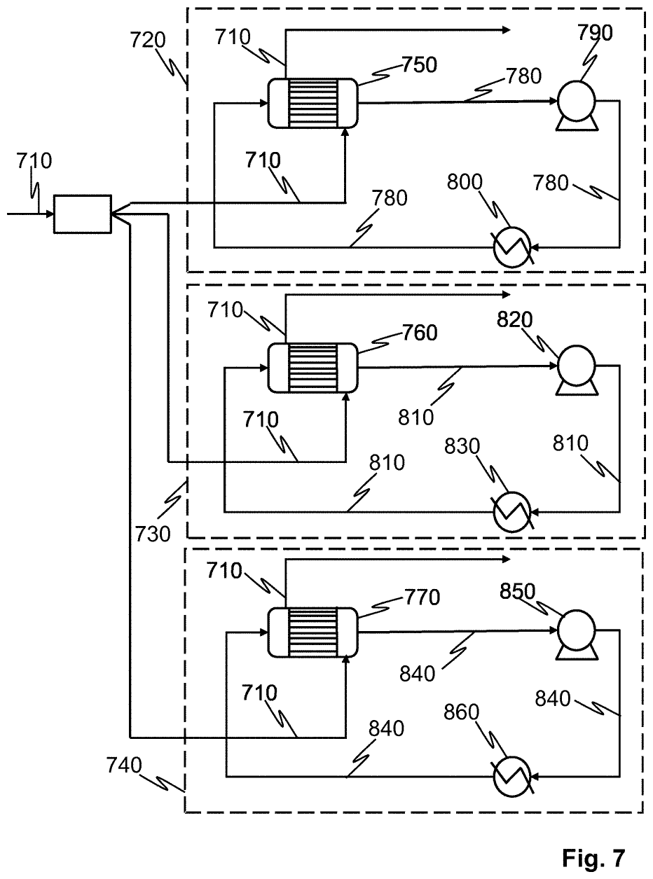

FIG. 7 shows a schematic drawing of the flowsheet used in the simulation. In FIG. 7, steam 710 is fed to the system and directed to three separate heat exchange systems 720, 730, 740, each heat exchange system 720, 730, 740 comprising its own heat exchanger 750, 760, 770, coolant liquid and coolant liquid circulation. Each heat exchanger 750, 760, 770 represents a rack of 42 servers. Steam 710 is in each heat exchange system fed to the tube side of the respective heat exchanger 750, 760, 770 and then outlet from the heat exchanger.

In the heat exchange system 720 drawn in FIG. 7 as the uppermost, the coolant liquid 780 is P2. P2 780 is fed to the shell side of the respective heat exchanger 750 and then circulated by a first pump 790 back to the shell side of the heat exchanger 750 representing in the simulation a rack of 42 servers via a second heat exchanger 800 configured to cool P2.

In the heat exchange system 730 drawn in FIG. 7 in the middle, the coolant liquid 810 is FC-40. FC-40 810 is fed to the shell side of the respective heat exchanger 760 and then circulated by a second pump 820 back to the shell side of the heat exchanger 760 representing in the simulation a rack of 42 servers via a third heat exchanger 830 configured to cool FC-40.

In the heat exchange system 740 drawn in FIG. 7 as the lowermost, the coolant liquid 840 is S5X. S5X 840 is fed to the shell side of the respective heat exchanger 770 and then circulated by a third pump 850 back to the shell side of the heat exchanger 770 representing in the simulation a rack of 42 servers via a fourth heat exchanger 860 configured to cool S5X.

The cooling duty of each rack (each heat exchanger 750, 760, 770) was set at 50 kW. The coolant liquid mass flow varied and the temperature of the coolant liquid inside the racks (heat exchangers 750, 760, 770) increased by 4-5° C. The pressure increase inside the pumps was set at 50 kPa and a mechanical efficiency of 0.6 was assumed.

Two cases were simulated, one in which the temperature of the racks (tube side of heat exchangers 750, 760, 770) was 37° C. and another in which the temperature of the racks (tube side of heat exchangers 750, 760, 770) was 27° C. The results of the simulations are shown in Tables 10 and 11, respectively. The results shown in Tables 10 and 11 are normalised values wherein the value obtained for P2 is set to be 1.

TABLE 10
Results of data center cooling simulations,
temperature of the rack 37° C.

| Coolant | P2 | FC-40 | S5X1 | Notes | |
|---|---|---|---|---|---|
| Cooling duty of rack | 1.0 | 1.0 | 1.0 | 50 | kW |
| Required coolant mass flow | 1.0 | 4.15 | 1.02 | Smaller-better | |
| Required coolant volume flow | 1.0 | 1.0 | 1.0 | Smaller-better | |
| Pump duty | 1.0 | 1.75 | 1.0 | Smaller-better | |
| Temperature (coolant to rack) | 1.0 | 1.0 | 1.0 | 31 | C. |
| Temperature (steam from rack) | 1.0 | 1.0 | 1.0 | 37 | C. |

| | | | | |
|---|---|---|---|---|
| Overall heat transfer coefficient | 1.0 | 0.79 | 0.99 | Higher-better |
| Pressure drop over the rack | 1.0 | 5.88 | 1.42 | Smaller-better |

TABLE 11
Results of data center cooling simulations,
temperature of the rack 27° C.

| Coolant | P2 | FC-40 | S5X1 | Notes | |
|---|---|---|---|---|---|
| Cooling duty of rack | 1.0 | 1.0 | 1.0 | 50 | kW |
| Required coolant mass flow | 1.0 | 4.32 | 1.02 | Smaller-better | |
| Required coolant volume flow | 1.0 | 1.80 | 1.0 | Smaller-better | |
| Pump duty | 1.0 | 1.81 | 1.0 | Smaller-better | |
| Temperature (coolant to rack) | 1.0 | 1.0 | 1.0 | 21 | C. |
| Temperature (steam from rack) | 1.0 | 1.0 | 1.0 | 27 | C. |

| | | | | |
|---|---|---|---|---|
| Overall heat transfer coefficient | 1.0 | 0.79 | 0.99 | Higher-better |
| Pressure drop over the rack | 1.0 | 6.10 | 1.46 | Smaller-better |

The results shown in Tables 10 and 11 indicate that P2 perform better as a coolant liquid in direct single phase immersion cooling of server racks than any of the commercially available coolant liquids FC-40 and S5X.

Comparing the results in Tables 10 and 11 obtained for P2 with those obtained for FC-40, it can be seen that P2 requires less than ¼ of the coolant liquid mass flow, a 70% to 80% smaller volume flow of the coolant liquid, a 70% to 80% lower pump power usage, and has a 21% better heat transfer than FC-40.

The differences in the results of Table 10 and 11 between P2 and S5X are smaller than between P2 and FC-40. However, the performance of P2 is still better than that of S5X in all studied aspects.

In Table 12 results of calculations of practical implications of using P2 as the coolant liquid in direct single phase immersion cooling versus using FC-40 as the coolant liquid in a small data center (500 racks of 42 servers) and in a normal size data center (10000 racks of 42 servers) are shown. In the calculations, the results of Table 10 and 11 were assumed valid and a constant volume of 1.11 m³ coolant liquid per rack was assumed.

TABLE 12
Estimations of using P2 and FC-40, respectively, as coolant
liquid in direct single phase immersion cooling in a
small data center (500 racks of 42 servers) and in a
normal sized data center (10000 racks of 42 servers).

| | Data center size | | | |
|---|---|---|---|---|
| | Small | | Normal | |
| | Number of racks | | | |
| | 500 | | 10000 | |
| Coolant | P2 | FC-40 | P2 | FC-40 |
| Required mass of coolant (ton) | 432 | 1030 | 8648 | 20592 |
| Required volume of coolant (m3) | 556 | 556 | 11120 | 11120 |
| Pump duty (kW) | 237 | 414 | 4738 | 8275 |

As can be deduced from Table 12, using P2 instead of FC-40 as a coolant liquid in direct single phase immersion cooling is estimated to yield about 600 ton less coolant liquid required and about 180 kW less (pump) electricity usage for cooling fora small data center or 12 000 ton less coolant liquid required and about for 3 500 kW less (pump) electricity usage for cooling for a normal sized data center. Also, the capital expenditure is smaller for designing piping, pumping and cooling of a 70% to 80% smaller flow rate.

### Example 5

### Thermal Conductivity Testing

Thermal conductivity, thermal diffusivity, and volumetric heat capacity (volumetric specific heat) of a renewable paraffinic composition corresponding to the renewable paraffinic composition P2 of Example 1 (P2) and of Fluorinert™ FC-40 (perfluorotri-n-butylamine) commercially available from 3M™ were measured according to ASTM D7896-19. The measurement time was 1 s and expected accuracy within 5%. The results are shown in Table 13 below. In table 13, rsd denotes relative standard deviation.

TABLE 13
Thermal conductivity, thermal diffusivity, and volumetric
heat capacity of P2 and FC-40, respectively.

| | | Thermal | | | | Volumetric | |
|---|---|---|---|---|---|---|---|
| | | conduc- | | Thermal | | Specific | |
| | | tivity | | Diffu- | | Heat | |
| Sam- | T | (W/ | % | sicity | % | (MJ/ | % |
| ple | (° C.) | (m · K)) | rsd | (mm²/s) | rsd | (m³K)) | rds |
| FC-40 | 5.4 | 0.068 | 0.000 | 0.056 | 0.000 | 1.214 | 0.001 |
| | 10.3 | 0.067 | 0.000 | 0.055 | 0.000 | 1.213 | 0.006 |
| | 20 | 0.067 | 0.000 | 0.054 | 0.000 | 1.233 | 0.001 |
| | 29.7 | 0.066 | 0.000 | 0.053 | 0.000 | 1.239 | 0.001 |
| | 39.4 | 0.065 | 0.000 | 0.052 | 0.000 | 1.254 | 0.007 |
| P2 | 5.6 | 0.132 | 0.000 | 0.075 | 0.000 | 1.749 | 0.005 |
| | 10.5 | 0.131 | 0.000 | 0.075 | 0.000 | 1.751 | 0.002 |
| | 20.2 | 0.129 | 0.000 | 0.073 | 0.000 | 1.761 | 0.003 |
| | 29.8 | 0.128 | 0.000 | 0.072 | 0.000 | 1.776 | 0.003 |
| | 39.4 | 0.126 | 0.000 | 0.071 | 0.000 | 1.784 | 0.002 |

As seen from Table 13, P2 has a significantly higher thermal conductivity compared to FC-40. Also the thermal diffusivity and volumetric specific heat of P2 is clearly higher than for FC-40. This is beneficial in direct single phase immersion cooling as a higher thermal conductivity and a higher thermal diffusivity allows for faster heat transfer from the immersed object to the coolant liquid. A higher volumetric specific heat is beneficial as it allows the coolant liquid to absorb more heat while increasing the temperature of the coolant liquid less compared to a coolant liquid with a lower volumetric specific heat. Hence, in view of Table 13, P2 has clear benefits over FC-40 as a coolant liquid in direct single phase immersion cooling.

Implementation and embodiments of the present invention are further discussed in the following numbered clauses:

1. Use of a renewable paraffinic composition comprising at least 80 wt-% paraffins in the C16-C19 range based on the total weight of the renewable paraffinic composition for direct single phase immersion cooling.

2. Use of the renewable paraffinic composition according to clause 1 for direct single phase immersion cooling of electronic hardware, preferably computer hardware, more preferably a server, or of a fuel cell.

3. Use of the renewable paraffinic composition according to clause 1 or 2 comprising circulating renewable paraffinic composition through a heat exchanging unit.

4. Use of the renewable paraffinic composition according to any one of the preceding clauses, wherein the temperature of operation is within a temperature range from ° C. to 90° C., preferably from 15° C. to 75° C., more preferably from 20° C. to 65° C.

5. Use of the renewable paraffinic composition according to any one of the preceding clauses, wherein the renewable paraffinic composition comprises more than 90 wt-%, preferably at least 95 wt-%, more preferably at least 98 wt-% paraffins based on the total weight of the renewable paraffinic composition.

6. Use of the renewable paraffinic composition according to any one of the preceding clauses, wherein the renewable paraffinic composition comprises 90 wt-% or more, preferably 95 wt-% or more, more preferably 98 wt-% or more paraffins in the C16-C19 range based on the total weight of the renewable paraffinic composition.

7. Use of the renewable paraffinic composition according to any one of the preceding clauses, wherein the renewable paraffinic composition comprises more than 60 wt-%, preferably more than 70 wt-%, more preferably more than 80 wt-%, even more preferably more than 90 wt-%, and most preferably more than 95 wt-% isoparaffins based on the total weight of the renewable paraffinic composition.

8. Use of the renewable paraffinic composition according to any one of the preceding clauses, wherein the renewable paraffinic composition comprises 5 wt-% or less naphthenes, preferably 2 wt-% or less naphthenes based on the total weight of the renewable paraffinic composition, more preferably the renewable paraffinic composition is essentially free from naphthenes.

9. Use of the renewable paraffinic composition according to any one of the preceding clauses, wherein the renewable paraffinic composition comprises less than 2 wt-% C15 and lighter paraffins and preferably less than 5 wt-%, more preferably less than 2 wt-% C20 and heavier paraffins, based on the total weight of the renewable paraffinic composition.

10. Use of the renewable paraffinic composition according to any one of the preceding clauses, wherein the renewable paraffinic composition comprises more than 37 wt-% C17 paraffins, based on the total weight of the renewable paraffinic composition.

11. Use of the renewable paraffinic composition according to any one of the preceding clauses, wherein the renewable paraffinic composition comprises more than 90 wt-% paraffins in the C17-C18 range, wherein the ratio of the amount of C18 i-paraffins to the amount of C18 n-paraffins is more than 40, based on the weight of the C18 i-paraffins and the weight of the C18 n-paraffins in the renewable paraffinic composition.

12. Use of the renewable paraffinic composition according to any one of the preceding clauses, wherein the renewable paraffinic composition has a flash point of at least 125° C., preferably at least 135° C., more preferably at least 140° C., even more preferably at least 145° C. (ENISO2719:2016).

13. Use of the renewable paraffinic composition according to any one of the preceding clauses, wherein the renewable paraffinic composition has a kinematic viscosity below 15 mm²/s, preferably below 10 mm²/s, more preferably below 5 mm²/s at 40° C. (EN ISO3104).

14. Use of the renewable paraffinic composition according to any one of the preceding clauses, wherein the renewable paraffinic composition has a density within the range from 700 to 850 kg/m³, preferably from 760 to 800 kg/m³, more preferably from 770 to 790 kg/m³kg/m³ at 20° C. (EN ISO12185).

15. Use of the renewable paraffinic composition according to any one of the preceding clauses, wherein the renewable paraffinic composition has a conductivity less than 1 pS/m at 22° C. (ISO6297:1997).

16. Use of the renewable paraffinic composition according to any one of the preceding clauses, wherein the biogenic carbon content of the renewable paraffinic composition is at least 50 wt-%, preferably at least 70 wt-%, more preferably at least 80 wt-%, even more preferably at least 90 wt-%, based on the total weight of carbon in the renewable paraffinic composition (ASTM D6866 (2020) or EN 16640 (2017)).

17. A direct single phase immersion cooling system comprising:
a bath comprising:
   renewable paraffinic composition comprising at least 80 wt-% paraffins in the C16-C19 range based on the total weight of the renewable paraffinic composition, and
an object to be cooled immersed in the renewable paraffinic composition.

18. The direct single phase immersion cooling system according to clause 17, comprising:
a heat exchanging unit; and
means for circulating renewable paraffinic composition through the heat exchanging unit.

19. The direct single phase immersion cooling system according to clause 17 or clause 18, wherein the direct single phase immersion cooling system is configured to maintain the temperature of the renewable paraffinic composition in the bath within a temperature range from 15° C. to 90° C., preferably from 15° C. to 65° C., more preferably from 20° C. to 75° C.

20. The direct single phase immersion cooling system according to any one of the preceding clauses 17-19, wherein more than one objects to be cooled are immersed in the renewable paraffinic composition.

21. The direct single phase immersion cooling system according to any one of the preceding clauses 17-20, wherein the object or objects to be cooled are electronic hardware preferably computer hardware, more preferably a server or servers, or wherein the object or objects to be cooled are a fuel cell or fuel cells.

22. The direct single phase immersion cooling system according to any one of the preceding clauses 17-21, wherein the means for circulating renewable paraffinic composition through the heat exchanging unit comprises pipes and optionally a pump or pumps.

23. A method for single phase immersion cooling comprising:
providing a bath comprising a renewable paraffinic composition comprising at least 80 wt-% paraffins in the C16-C19 range based on the total weight of the renewable paraffinic composition; and
immersing an object to be cooled in the renewable paraffinic composition.

24. The method for single phase immersion cooling according to clause 23, comprising circulating renewable paraffinic composition through a heat exchanging unit.

25. The method for single phase immersion cooling according to clause 23 or clause 24 comprising maintaining the temperature of renewable paraffinic composition in the bath within a temperature range from 15° C. to 90° C., preferably from 15° C. to 75° C., more preferably from 20° C. to 65° C.

26. The method according to any one of the preceding clauses 23-25, comprising immersing more than one objects to be cooled in the renewable paraffinic composition.

27. The method according to any one of the preceding clauses 23-26, wherein the object or objects to be cooled are electronic hardware preferably computer hardware, more preferably a server or servers or wherein the object or objects to be cooled are a fuel cell or fuel cells.

Various embodiments have been presented. It should be appreciated that in this document, words comprise, include and contain are each used as open-ended expressions with no intended exclusivity.

The foregoing description has provided by way of non-limiting examples of particular implementations and embodiments a full and informative description of the best mode presently contemplated by the inventors for carrying out the invention. It is however clear to a person skilled in the art that the invention is not restricted to details of the embodiments presented in the foregoing, but that it can be implemented in other embodiments using equivalent means or in different combinations of embodiments without deviating from the characteristics of the invention. The embodiments of the present disclosure may be combined, in whole or in part, with each other to form further embodiment(s) of the present disclosure. Further, the particular features or characteristics illustrated or described in connection with various embodiments may be combined, in whole or in part, with the features or characteristics of one or more other embodiments without limitation. Such modifications and variations are intended to be included within the scope of the present disclosure.

Furthermore, some of the features of the afore-disclosed example embodiments may be used to advantage without the corresponding use of other features. As such, the foregoing description shall be considered as merely illustrative of the principles of the present invention, and not in limitation thereof. Hence, the scope of the invention is only restricted by the appended patent claims.

1.-17. (canceled)

18. A direct single phase immersion cooling system, comprising:
a bath containing:
renewable paraffinic composition including at least 80 wt-% paraffins in a C16-C19 range based on a total weight of the renewable paraffinic composition; and
electronic hardware immersed in the renewable paraffinic composition.

19. A method for single phase immersion cooling the method comprising:
providing a bath containing a renewable paraffinic composition comprising at least 80 wt-% paraffins in a C16-C19 range based on a total weight of the renewable paraffinic composition; and
immersing electronic hardware in the renewable paraffinic composition.

20. The method according to claim 19, wherein the electronic hardware is a server or other computer hardware.

21. The method according to claim 19, comprising:
circulating renewable paraffinic composition through a heat exchanging unit.

22. The method according to claim 19, wherein a temperature of operation is within a temperature range from 15° C. to 90° C.

23. The method according to claim 19, wherein the renewable paraffinic composition comprises:
more than 90 wt-% paraffins based on the total weight of the renewable paraffinic composition.

24. The method according to claim 19, wherein the renewable paraffinic composition comprises:
90 wt-% or more paraffins in the C16-C19 range based on the total weight of the renewable paraffinic composition.

25. The method according to claim 19, wherein the renewable paraffinic composition comprises:
more than 60 wt-% isoparaffins based on the total weight of the renewable paraffinic composition.

26. The method according to claim 19, wherein the renewable paraffinic composition comprises:
5 wt-% or less naphthenes based on the total weight of the renewable paraffinic composition.

27. The method according to claim 19, wherein the renewable paraffinic composition comprises:
less than 2 wt-% C15 and lighter paraffins; and
less than 5 wt-% C20 and heavier paraffins based on the total weight of the renewable paraffinic composition.

28. The method according to claim 19, wherein the renewable paraffinic composition comprises:
more than 37 wt-% C17 paraffins based on the total weight of the renewable paraffinic composition.

29. The method according to claim 19, wherein the renewable paraffinic composition comprises:
more than 90 wt-% paraffins in the C17-C18 range; and
wherein a ratio of an amount of C18 i-paraffins to an amount of C18 n-paraffins is more than 40 based on a weight of the C18 i-paraffins and the weight of the C18 n-paraffins in the renewable paraffinic composition.

30. The method according to claim 19, wherein the renewable paraffinic composition has a flash point of at least 125° C. (ENISO2719:2016).

31. The method according to claim 19, wherein the renewable paraffinic composition has a kinematic viscosity below 15 mm2/s at 40° C. (EN ISO3104).

32. The method according to claim 19, wherein the renewable paraffinic composition has a density within a range from 700 to 850 kg/m3 at 20° C. (EN ISO12185).

33. The method according to claim 19, wherein the renewable paraffinic composition has an electrical conductivity less than 1 pS/m at 22° C. (ISO6297:1997).

34. The method according to claim 19, wherein the renewable paraffinic composition has a volumetric specific heat within a range from 1.60 MJ/(m3K) to 1.90 MJ/(m3K) as measured according to ASTM D7896-19 at 20° C., and/or a thermal conductivity within a range from 0.11 W/(m·K) to 0.15 W/(m·K) as measured according to ASTM D7896-19 at 20° C., and/or a thermal diffusivity within a range from 0.06 mm2/s to 0.09 mm2/s as measured according to ASTM D7896-19 at 20° C.

35. The method according to claim 19, wherein a biogenic carbon content of the renewable paraffinic composition is at least 50 wt-% based on a total weight of carbon in the renewable paraffinic composition (ASTM D6866 (2020) or EN 16640 (2017)).

36. The direct single phase immersion cooling system according to claim 18, comprising:
a heat exchanging unit; and
means for circulating renewable paraffinic composition through the heat exchanging unit.

37. The direct single phase immersion cooling system according to claim 18, wherein the electronic hardware is a server or other computer hardware.
